(19) United States
(12) Patent Application Publication
(10) Pub. No.: US 2026/0344274 A1
(43) Pub. Date: Oct. 29, 2026

(54) Display Panel and Display Apparatus

(71) Applicant: BOE TECHNOLOGY GROUP CO., LTD., Beijing (CN)

(72) Inventors: Tao WANG, Beijing (CN); Mingche HSIEH, Beijing (CN)

(21) Appl. No.: 19/731,505

(22) Filed: Jul. 6, 2026

Related U.S. Application Data
(63) Continuation of application No. 18/992,839, filed on Apr. 16, 2024.

(30) Foreign Application Priority Data
May 29, 2023 (CN) 202310623005.9

(51) Int. Cl. H10K 59/80

(52) U.S. Cl. CPC H10K 59/8792; H10K 59/873

(57) ABSTRACT

A display panel has a display area and a peripheral area surrounding the display area. The display panel includes a back plate, an encapsulation structure arranged on the back plate, an anti-peeping organic layer arranged on a side, away from the back plate, of the encapsulation structure, and an anti-peeping structure arranged on a side, away from the encapsulation structure, of the anti-peeping organic layer. The encapsulation structure includes an organic encapsulation layer, and the organic encapsulation layer covers the display area and extends to the peripheral area. The anti-peeping organic layer covers the display area and extends to the peripheral area, and an edge of the anti-peeping organic layer is located on a side, away from the display area, of an edge of the organic encapsulation layer. The anti-peeping structure is at least located in the display area.

### CROSS-REFERENCE TO RELATED APPLICATIONS

This application is a continuation of U.S. Patent Application No. 18/992,839, filed on Apr. 16, 2024, which is a national phase entry under 35 USC 371 of International Patent Application No. PCT/CN2024/088128, filed on Apr. 16, 2024, which claims priority to Chinese Patent Application No. 202310623005.9, filed on May 29, 2023, which are incorporated herein by reference in their entirety.

### BACKGROUND OF THE INVENTION

### FIELD OF THE INVENTION

The present disclosure relates to the field of display technologies, and in particular, to a display panel and a display apparatus.

### DESCRIPTION OF RELATED ART

With the continuous development of display technologies, display apparatuses have gradually come throughout people's lives. Organic light-emitting diode (OLED) display panels are widely used in smart products such as mobile phones, televisions and notebook computers due to advantages of self-luminescence, low power consumption, wide viewing angle, fast response speed and high contrast.

### SUMMARY OF THE INVENTION

In an aspect, a display panel is provided. The display panel has a display area and a peripheral area surrounding the display area. The display panel includes a back plate, an encapsulation structure disposed on the back plate, an anti-peeping organic layer disposed on a side of the encapsulation structure away from the back plate, and an anti-peeping structure disposed on a side of the anti-peeping organic layer away from the encapsulation structure. The encapsulation structure includes an organic encapsulation layer, and the organic encapsulation layer covers the display area and extends to the peripheral area. The anti-peeping organic layer covers the display area and extends to the peripheral area, and an edge of the anti-peeping organic layer is located on a side of an edge of the organic encapsulation layer away from the display area. The anti-peeping structure is at least located in the display area.

In some embodiments, the display panel further includes at least one encapsulation dam and an anti-crack structure that are disposed in the peripheral area and surrounding the display area. The anti-crack structure is located on a side of the at least one encapsulation dam away from the display area, and an encapsulation dam closest to the display area in the at least one encapsulation dam is a first encapsulation dam. The edge of the organic encapsulation layer is located between the first encapsulation dam and the display area. The edge of the anti-peeping organic layer is located between an edge of the first encapsulation dam proximate to the display area and an edge of the anti-crack structure away from the display area.

In some embodiments, the at least one encapsulation dam includes a plurality of encapsulation dams, and the edge of the anti-peeping organic layer is located between two adjacent encapsulation dams.

In some embodiments, the edge of the anti-peeping organic layer is located between an encapsulation dam furthest away from the display area in the at least one encapsulation dam and the anti-crack structure.

In some embodiments, the edge of the anti-peeping organic layer is located on any encapsulation dam.

In some embodiments, the edge of the anti-peeping organic layer is located on the anti-crack structure.

In some embodiments, the at least one encapsulation dam includes at least one first target encapsulation dam, and the first target encapsulation dam is located on a side of the edge of the anti-peeping organic layer proximate to the display area. At least one of a side surface of the first target encapsulation dam proximate to the display area, an upper surface of the first target encapsulation dam, and a side surface of the first target encapsulation dam away from the display area is provided with a first flow limiting structure thereon.

In some embodiments, in a case where the edge of the anti-peeping organic layer is located between the two adjacent encapsulation dams, the at least one encapsulation dam includes at least one second target encapsulation dam, and the second target encapsulation dam is located on a side of the edge of the anti-peeping organic layer away from the display area and adjacent to the edge of the anti-peeping organic layer. A side surface of the second target encapsulation dam proximate to the display area is provided with a first flow limiting structure thereon.

In some embodiments, in a case where the edge of the anti-peeping organic layer is located between the encapsulation dam furthest away from the display area in the at least one encapsulation dam and the anti-crack structure, a side surface of the anti-crack structure proximate to the display area is provided with a first flow limiting structure thereon.

In some embodiments, in a case where the edge of the anti-peeping organic layer is located on any encapsulation dam, the at least one encapsulation dam includes a third target encapsulation dam, and the third target encapsulation dam is located under the edge of the anti-peeping organic layer. A side surface of the third target encapsulation dam proximate to the display area and/or an upper surface of the third target encapsulation dam are each provided with a first flow limiting structure thereon.

In some embodiments, in a case where the edge of the anti-peeping organic layer is located on the anti-crack structure, a side surface of the anti-crack structure proximate to the display area and/or an upper surface of the anti-crack structure are each provided with a first flow limiting structure thereon.

In some embodiments, the first flow limiting structure includes at least one first groove.

In some embodiments, the back plate includes a substrate, and an insulating dielectric layer and a planarization layer that are sequentially stacked on the substrate. An upper surface of the insulating dielectric layer is provided with at least one slit therein, and the slit is disposed around the display area. The planarization layer includes an anti-crack pattern located in the peripheral area, and the anti-crack pattern covers the at least one slit and is disposed around the display area. The anti-crack structure includes the at least one slit and the anti-crack pattern.

In some embodiments, in a case where the side surface of the anti-crack structure proximate to the display area and/or the upper surface of the anti-crack structure are each provided with the at least one first groove thereon, an orthogonal projection of the first groove on the substrate and an orthogonal projection of the slit on the substrate do not overlap, and the first groove extends through or partially extends through the anti-crack pattern from an upper surface of the anti-crack pattern; and/or the orthogonal projection of the first groove on the substrate and the orthogonal projection of the slit on the substrate overlap, and the first groove partially extends through the anti-crack pattern from an upper surface of the anti-crack pattern.

In some embodiments, the display panel further includes a light-filter structure disposed between the encapsulation structure and the anti-peeping organic layer. The light-filter structure includes a black matrix layer and a plurality of filter portions, and the black matrix layer includes a first portion located in the display area and a second portion located in the peripheral area. The first portion of the black matrix layer is provided with a plurality of openings therein, and each filter portion is located in an opening. The second portion of the black matrix layer is provided with a second flow limiting structure thereon, and the second flow limiting structure is located between the edge of the organic encapsulation layer and the edge of the anti-peeping organic layer.

In some embodiments, the display panel further includes at least one encapsulation dam and an anti-crack structure, and an encapsulation dam closest to the display area in the at least one encapsulation dam is a first encapsulation dam. The second flow limiting structure is located between the edge of the organic encapsulation layer and the first encapsulation dam. Alternatively, the second flow limiting structure is located on the anti-crack structure.

In some embodiments, the at least one encapsulation dam includes a plurality of encapsulation dams, and the second flow limiting structure is located between two adjacent encapsulation dams.

In some embodiments, the second flow limiting structure is located on any encapsulation dam.

In some embodiments, the second flow limiting structure is located between an encapsulation dam farthest away from the display area in the at least one encapsulation dam and the anti-crack structure.

In some embodiments, the second flow limiting structure includes at least one second groove extending through or partially extending through the black matrix layer from an upper surface of the black matrix layer.

In some embodiments, a shape of the first groove and/or a shape of the second groove include at least one of a circle, an ellipse or a polygon; and/or the first groove and/or the second groove are each in a long strip shape, and the long strip shape extends in a straight line, a wavy line or a broken line.

In some embodiments, in a case where the shape of the first groove or the second groove includes a circle, an ellipse or a polygon, a maximum value of a dimension of the first groove or the second groove is d1, and 5 μm ≤ d1 ≤ 20 μm; an interval between any two adjacent first grooves or between any two adjacent second grooves is d2, and 5 μm ≤ d2 ≤ 20 μm.

In some embodiments, in a case where the first groove or the second groove is in a long strip shape, a width of the first groove or the second groove is d3, and 5 μm ≤ d3 ≤ 20 μm; an interval between any two adjacent first grooves or between any two adjacent second grooves is d4, and 5 μm ≤ d4 ≤ 20 μm.

In some embodiments, in a case where the first flow limiting structure includes a plurality of first grooves, the plurality of first grooves are arranged into at least one column and a plurality of rows, and multiple first grooves in each column are arranged along the edge of the anti-peeping organic layer.

In some embodiments, in a case where the plurality of first grooves are arranged in a plurality of columns and a plurality of rows, multiple first grooves in each row are arranged in a direction perpendicular to the edge of the anti-peeping organic layer, and first grooves in any two adjacent rows are aligned or staggered in a column direction.

In some embodiments, in a case where the second flow limiting structure includes a plurality of second grooves, the plurality of second grooves are arranged into at least one column and a plurality of rows, and multiple second grooves in each column are arranged along the edge of the anti-peeping organic layer.

In some embodiments, in a case where the plurality of second grooves are arranged in a plurality of columns and a plurality of rows, multiple second grooves in each row are arranged in a direction perpendicular to the edge of the anti-peeping organic layer, and second grooves in any two adjacent rows are aligned or staggered in a column direction.

In some embodiments, a material of the organic encapsulation layer includes at least one of acrylic resin, epoxy resin, phenolic resin, polyamide resin or polyimide resin, a thickness of the organic encapsulation layer is d5, and 1 μm ≤ d5 ≤ 4 μm.

In some embodiments, the anti-peeping structure includes a plurality of light-shielding strips disposed at intervals, any two adjacent light-shielding strips have a light-transmitting area therebetween, and the light-shielding strips and light-transmitting areas are alternately disposed in a set direction.

In some embodiments, the anti-peeping structure is in a grid shape.

In another aspect, a display apparatus is provided. The display apparatus includes a driving circuit board and the display panel as described in any of the above embodiments. The driving circuit board is electrically connected to the display panel.

### BRIEF DESCRIPTION OF THE DRAWINGS

The terms Fig., Figs., Figure, and Figures are used interchangeably in the specification to refer to the corresponding figures in the drawings.

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a plan diagram showing a structure of a display apparatus, in accordance with some embodiments;

FIG. 2 is a structural diagram of a display apparatus, in accordance with some embodiments;

FIG. 3 is a sectional view showing a structure of a display panel corresponding to a single light-emitting element, in accordance with some embodiments;

FIG. 4 is a sectional view showing a structure of a display panel obtained along a section line DD in FIG. 1;

FIG. 5 is a sectional view showing a structure of a display panel obtained along a section line BB in FIG. 1;

FIG. 6 is a sectional view showing a structure of a display panel obtained along a section line BB in FIG. 1;

FIG. 7 is a sectional view showing a structure of a display panel obtained along a section line BB in FIG. 1;

FIG. 8 is a sectional view showing a structure of a display panel obtained along a section line BB in FIG. 1;

FIG. 9 is a sectional view showing a structure of a display panel obtained along a section line BB in FIG. 1;

FIG. 10 is a sectional view showing a structure of a display panel obtained along a section line BB in FIG. 1;

FIG. 11 is a sectional view showing a structure of a display panel obtained along a section line BB in FIG. 1;

FIG. 12 is a sectional view showing a structure of a display panel obtained along a section line BB in FIG. 1;

FIG. 13 is a sectional view showing a structure of a display panel obtained along a section line BB in FIG. 1;

FIG. 14 is an enlarged structural diagram of a region E in FIG. 13;

FIG. 15 is a plan diagram showing a structure of a display panel, in accordance with some embodiments;

FIG. 16 is a plan diagram showing a structure of another display panel, in accordance with some embodiments ;

FIG. 17 is a schematic diagram showing a plan structure of a first flow limiting structure in a region C in FIG. 10;

FIG. 18 is a schematic diagram showing a plan structure of another first flow limiting structure in a region C in FIG. 10;

FIG. 19 is a schematic diagram showing a plan structure of another first flow limiting structure in a region C in FIG. 10;

FIG. 20 is a schematic diagram showing a plan structure of another first flow limiting structure in a region C in FIG. 10;

FIG. 21 is a sectional view showing a structure of a display panel obtained along a section line BB in FIG. 1;

FIG. 22 is a plan diagram showing a structure of an anti-peeping structure, in accordance with some embodiments; and

FIG. 23 is a plan diagram showing a structure of another anti-peeping structure, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term "comprise" and other forms thereof such as the third-person singular form "comprises" and the present participle form "comprising" are construed as open and inclusive, i.e., "including, but not limited to". In the description of the specification, the terms such as "one embodiment", "some embodiments", "exemplary embodiments", "example", "specific example" or "some examples" are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as "first" and "second" are used for descriptive purposes only, and are not to be construed as indicating or implying the relative importance or implicitly indicating the number of indicated technical features. Thus, features defined with "first" or "second" may explicitly or implicitly include one or more of the features. In the description of the embodiments of the present disclosure, the term "a plurality of" or "the plurality of" means two or more unless otherwise specified.

In the description of some embodiments, the expressions "coupled" and "connected" and derivatives thereof may be used. The term "connection" should be understood in a broad sense. For example, the "connection" may be a fixed connection, a detachable connection, or of an integrated structure; it may be a direct connection or an indirect connection by an intermediate medium. The term "coupled" indicates, for example, that two or more components are in direct physical or electrical contact. However, the term "coupled" or "communicatively coupled" may also mean that two or more components are not in direct contact with each other, but still cooperate or interact with each other. The embodiments disclosed herein are not necessarily limited to the content herein.

The phrase "at least one of A, B and C" has a same meaning as the phrase "at least one of A, B or C", and they both include the following combinations of A, B and C: only A, only B, only C, a combination of A and B, a combination of A and C, a combination of B and C, and a combination of A, B and C.

The phrase "A and/or B" includes the following three combinations: only A, only B, and a combination of A and B.

The phrase "applicable to" or "configured to" as used herein indicates an open and inclusive expression, which does not exclude apparatuses that are applicable to or configured to perform additional tasks or steps.

The term "about", "substantially" or "approximately" as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as "parallel", "perpendicular" or "equal" as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term "parallel" includes absolute parallelism and approximate parallelism, and an acceptable range of deviation of the approximate parallelism may be a deviation within 5°; the term "perpendicular" includes absolute perpendicularity and approximate perpendicularity, and an acceptable range of deviation of the approximate perpendicularity may also be a deviation within 5°; and the term "equal" includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

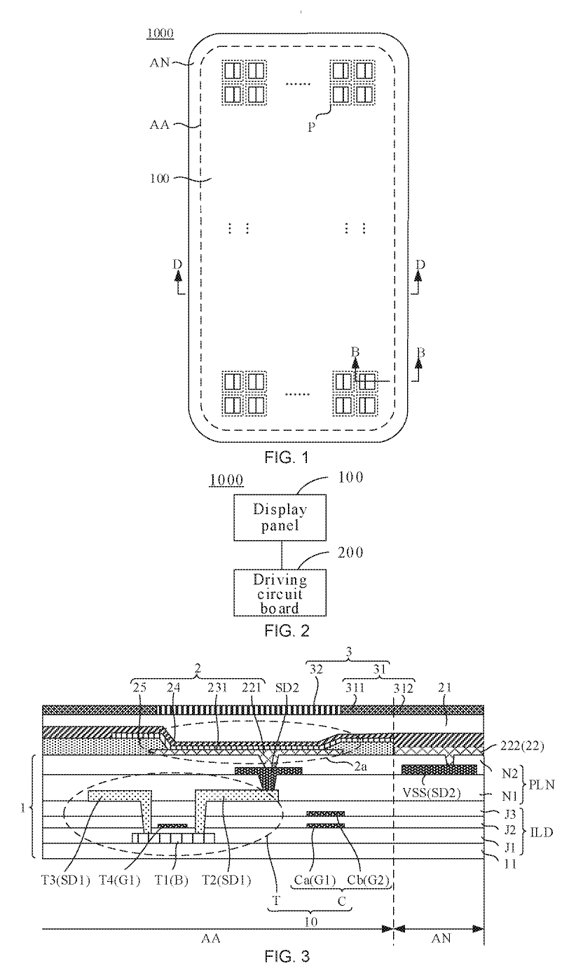

As shown in FIGS. 1 and 2, the display apparatus 1000 includes a display panel 100 and a driving circuit board 200. The driving circuit board 200 is configured to send a driving signal (e.g., a display driving signal) to the display panel 100, thereby driving the display panel 100 to display an image.

For example, the driving circuit board 200 includes but is not limited to a printed circuit board (PCB) or a flexible printed circuit (FPC).

For example, as shown in FIG. 1, a type of the display panel 100 varies, and may be selected depending on actual needs.

For example, as shown in FIG. 1, the display panel 100 includes, but is not limited to, an organic light-emitting diode (OLED) display panel, a quantum dot light-emitting diode (QLED) display panel, or a micro light-emitting diode (micro LED) display panel, which is not specifically limited in the embodiments of the present disclosure.

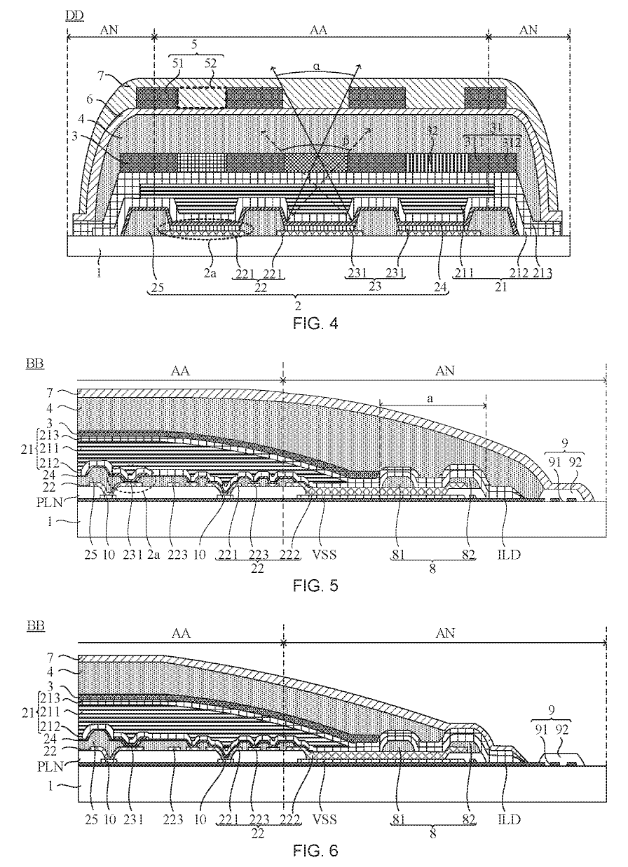

In the embodiments of the present disclosure, A(B) in the reference numerals means that A belongs to B. For example, 222(22) indicates that a transfer electrode 222 is located in an anode layer 22. FIGS. 1 and 2 are each a structural diagram of a display apparatus 1000. FIG. 3 is sectional view showing a structure of a display panel 100 corresponding to a single light-emitting element 2a. FIG. 4 is a sectional view showing a structure of a display panel 100 obtained along a section line DD in FIG. 1, and to facilitate clearly describing a film structure of a display panel 100, only three light-emitting elements 2a are shown in the figure, and the number of the light-emitting elements 2a included in the display panel 100 is not limited to three.

FIGS. 5 to 13 and FIG. 21 are each a sectional view showing a structure of the display panel 100 obtained along a section line BB in FIG. 1. To facilitate clearly describing a positional relationship between an organic encapsulation layer 211 and an anti-peeping organic layer 4, and an anti-peeping principle of an anti-peeping structure 5, only some film layer structures included in the display panel 100 is shown in the figures. It can be understood that the display panel 100 may further include other structures in addition to the film layer structures shown in the figures.

To facilitate clearly describing a method of providing a first flow limiting structure L1 on an anti-crack structure 9, in an enlarged structural diagram of a region E in FIG. 13 shown in FIG. 14, only a substrate 11, an insulating dielectric layer ILD, an anti-crack structure 9 and a first flow limiting structure L1 disposed on the anti-crack structure 9 are shown.

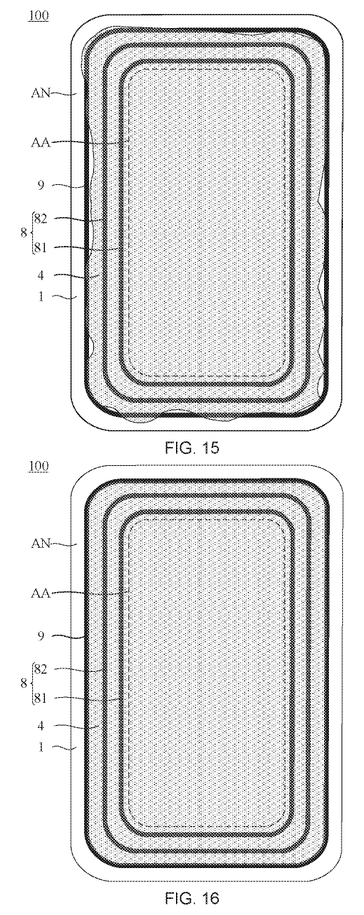

FIGS. 15 and 16 are each a plan diagram showing a structure of a display panel 100. To facilitate clearly describing relative positions between an edge of the anti-peeping organic layer 4 and an encapsulation dam 8 and an anti-crack structure 9, only a back plate 1, an encapsulation dam 8, an anti-crack structure 9 and an anti-peeping organic layer 4 are shown in FIGS. 15 and 16.

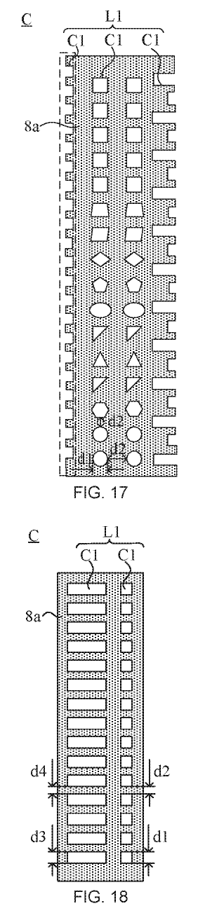

To facilitate clearly describing a structure and a size of the first flow limiting structure L1, FIGS. 17 to 20 are each a partial enlarged diagram showing a plan structure of a first target encapsulation dam 8a shown in a region C in FIG. 10. A plurality of first grooves C1 shown in FIGS. 17 to 20 are each a partial enlarged diagram of the first flow limiting structure L1 disposed on the first target encapsulation dam 8a. The first target encapsulation dam 8a may have an annular structure surrounding a display area AA, and a shape of the annular structure matches a shape of a boundary line of the display area AA and/or a shape of a peripheral area AN. The specific arrangement of the first flow limiting structure L1 and the first grooves C1 included therein are related to the shape of the first target encapsulation dam 8a, and each column of first grooves C1 may be multiple hole-shaped grooves arranged in an annular shape or an annular long strip groove, and is not limited to a linear arrangement. FIGS. 22 and 23 are each a plan diagram showing a structure of an anti-peeping structure 5.

Some embodiments of the present disclosure will be exemplarily described below by considering an example in which the display panel 100 is the OLED display panel.

In some embodiments, as shown in FIGS. 3 and 4, the display panel 100 includes a back plate 1, a light-emitting structure 2, an encapsulation structure 21 and a light-filter structure 3. The back plate 1 includes a substrate 11, and a driving circuit layer, an insulating dielectric layer ILD and a planarization layer PLN that are stacked on the substrate 11. The light-emitting structure 2 is disposed on a side of the planarization layer PLN away from the substrate 11.

As shown in FIGS. 1 and 4, the display panel 100 has a display area AA and a peripheral area AN surrounding the display area AA. The light-emitting structure 2 is located in the display area AA.

For example, as shown in FIG. 5, the substrate 11 includes but is not limited to a glass substrate, a quartz substrate, a plastic substrate, a sapphire substrate, a polyimide (PI) film or a silicon-based substrate.

In some embodiments, as shown in FIG. 3, the driving circuit layer includes a semiconductor layer B, a first gate conductive layer G1, a second gate conductive layer G2, a first source-drain conductive layer SD1 and a second source-drain conductive layer SD2 that are disposed sequentially. The insulating dielectric layer ILD includes a first insulating layer J1, a second insulating layer J2 and a third insulating layer J3 that are disposed sequentially. The planarization layer PLN includes a first planarization layer N1 and a second planarization layer N2 that are disposed sequentially.

For example, as shown in FIG. 3, the first insulating layer J1 is provided between the semiconductor layer B and the first gate conductive layer G1, the second insulating layer J2 is provided between the first gate conductive layer G1 and the second gate conductive layer G2, the third insulating layer J3 is provided between the first source-drain conductive layer SD1 and the second gate conductive layer G2, the first planarization layer N1 is provided between the first source-drain conductive layer SD1 and the second source-drain conductive layer SD2, and the second planarization layer N2 is provided between the second source-drain conductive layer SD2 and an anode layer 22.

For example, as shown in FIGS. 3 and 4, the insulating dielectric layer ILD (e.g., the first insulating layer J1, the second insulating layer J2 and the third insulating layer J3) is made of an insulating material. A material of the insulating dielectric layer ILD includes, but is not limited to, any of silicon nitride (SiNx), silicon oxide (SiOx), silicon oxynitride (SiON), aluminum oxide (Al₂O₃) and titanium oxide (TiO₂). Here, only an exemplary description is made and the present disclosure is not limited thereto.

For example, the insulating dielectric layer ILD may be formed by chemical vapor deposition (CVD), atomic layer deposition (ALD) or sputtering.

For example, as shown in FIGS. 3 and 4, a material of the planarization layer PLN (e.g., the first planarization layer N1 and the second planarization layer N2) includes, but is not limited to, any of acrylate polymers, epoxy polymers or polyurethane polymers.

For example, the planarization layer PLN may be formed by inkjet printing (Ink-Jet Printing, IJP), screen printing, flash evaporation, plasma enhanced chemical vapor deposition (PECVD) or plasma enhanced atomic layer deposition (PEALD).

Here, only an exemplary description is made and is not used as a limitation in the present disclosure.

For example, as shown in FIG. 3, the driving circuit layer includes a plurality of pixel circuits 10, and each pixel circuit 10 includes at least one transistor T (e.g., a thin film transistor) and a capacitor C, which includes but is not limited thereto.

In some examples, as shown in FIG. 3, the transistor T includes a semiconductor pattern T1, a source T2, a drain T3 and a gate T4. The semiconductor pattern T1 is located in the semiconductor layer B, the gate T4 is located in the first gate conductive layer G1, and the source T2 and the drain T3 are located in the first source-drain conductive layer SD1.

In some examples, as shown in FIG. 3, the capacitor C includes a first electrode plate Ca and a second electrode plate Cb. The first electrode plate Ca of the capacitor C is located in the first gate conductive layer G1, and the second electrode plate Cb of the capacitor is located in the second gate conductive layer G2.

For example, as shown in FIG. 3, a first voltage signal line is disposed in the second source-drain conductive layer SD2 in the driving circuit layer, and the first voltage signal line is configured to transmit a first voltage signal vss.

In some examples, the first voltage signal line includes a first voltage signal sub-line located in the display area AA and a first voltage signal bus VSS located in the peripheral area AN, and the first voltage signal sub-line and the first voltage signal bus VSS are electrically connected.

The introduction of each film layer included in the driving circuit layer is as follows.

For example, a material of the semiconductor layer B includes amorphous silicon, monocrystalline silicon, polycrystalline silicon, or a metal oxide semiconductor material. For example, the material of the semiconductor layer B includes indium gallium zinc oxide (IGZO) or zinc oxide (ZnO), and the present disclosure is not limited thereto. The semiconductor layer B includes semiconductor patterns T1 of all the transistors.

For example, overlapping portions of the first gate conductive layer G1 and the semiconductor layer B constitute gates of the transistors. The first gate conductive layer G1 includes gates of all the transistors and a plurality of gate scanning lines.

For example, the first source-drain conductive layer SD1 includes a plurality of first signal lines (e.g., data lines), a plurality of first electrodes, and the like.

For example, the second source-drain conductive layer SD2 includes a plurality of second signal lines (e.g., second voltage signal lines), a plurality of second electrodes, and the like.

For example, materials of the first gate conductive layer G1, the second gate conductive layer G2, the first source-drain conductive layer SD1 and the second source-drain conductive layer SD2 includes conductive metals. For example, the materials of the first gate conductive layer G1, the second gate conductive layer G2, the first source-drain conductive layer SD1 and the second source-drain conductive layer SD2 each include, but are not limited to, at least one of aluminum, copper, molybdenum or gold, and the present disclosure is not limited thereto.

The first gate conductive layer G1, the second gate conductive layer G2, the first source-drain conductive layer SD1 and the second source-drain conductive layer SD2 may each adopt a single-layer structure or a stacked structure. For example, in a case where the second source-drain conductive layer SD2 adopts a stacked structure, the second source-drain conductive layer SD2 may include molybdenum/copper/molybdenum metal layers stacked in sequence. Here, only an exemplary description is made and is not used as a limitation in the present disclosure.

In some embodiments, as shown in FIGS. 3 and 4, the light-emitting structure 2 includes an anode layer 22, a pixel defining layer 25, a light-emitting functional layer 23 and a cathode layer 24 that are stacked. The light-emitting functional layer 23 and the pixel defining layer 25 are located between the anode layer 22 and the cathode layer 24. The anode layer 22 is closer to the back plate 1 than the cathode layer 24.

For example, as shown in FIGS. 3 and 4, a material of the anode layer 22 includes, but is not limited to, at least one of gold (Au), silver (Ag) or platinum (Pt).

In some examples, the anode layer 22 is made of a transparent conductive material, and the material of the anode layer 22 includes, but is not limited to, at least one of indium tin oxide (ITO), indium zinc oxide (IZO) or other transparent conductive materials.

For example, the anode layer 22 is formed by evaporation, sputtering or ALD.

For example, as shown in FIGS. 3 and 4, a material of the cathode layer 24 includes, but is not limited to, magnesium-silver alloy. In some examples, the cathode layer 24 is made of a transparent conductive material, and the material of the cathode layer 24 includes, but is not limited to, at least one of ITO, IZO or other transparent conductive materials.

For example, the cathode layer 24 is formed by evaporation, sputtering or ALD.

In some embodiments, as shown in FIGS. 3 and 4, the light-emitting functional layer 23 adopts a single-layer structure, and the light-emitting functional layer 23 includes an emitting material layer (EML, also referred to as an organic light-emitting layer).

In some other embodiments, the light-emitting functional layer 23 adopts a stacked structure. In addition to the EML, the light-emitting functional layer 23 further includes at least one of an electron injection layer (EIL), an electron transport layer (electron transporting layer, ETL), a hole block layer (HBL), an electron block layer (EBL), a hole transport layer (hole transporting layer, HTL) and a hole injection layer (HIL).

For example, the EBL, the HTL and the HIL are disposed between the EML and the anode layer 22, and the EBL is closer to the EML than the HTL and the HIL.

For example, the EIL, the ETL and the HBL are disposed between the EML and the cathode layer 24, and the HBL is closer to the EML than the EIL and the ETL.

For example, the light-emitting functional layer 23 is formed by evaporation or inkjet printing.

Here, only an exemplary description is made and is not used as a limitation in the present disclosure.

In some embodiments, as shown in FIGS. 3 and 4, the anode layer 22 includes a plurality of anodes 221 located in the display area AA. The light-emitting functional layer 23 includes a plurality of light-emitting portions 231 disposed in one-to-one correspondence with the plurality of anodes 221. The pixel defining layer 25 has a plurality of openings, and each light-emitting portion 231 is located in an opening.

For example, as shown in FIGS. 3 and 4, the cathode layer 24 has a whole-layer structure. Accordingly, the anode 221, the light-emitting portion 231 and a portion of the cathode layer 24 corresponding to the opening form a light-emitting element 2a, that is, the light-emitting structure 2 includes a plurality of light-emitting elements 2a.

For example, each light-emitting portion 231 is configured to emit at least one of lights of a plurality of colors, and each light-emitting element 2a is configured to emit at least one of lights of a plurality of colors.

In some examples, as shown in FIGS. 3 and 4, a single light-emitting element 2a may emit a light of a color, and the lights emitted by the plurality of light-emitting elements 2a have the same color.

In some other examples, as shown in FIGS. 3 and 4, a single light-emitting element 2a may emit a light of a color, and the lights emitted by the plurality of light-emitting elements 2a have not completely the same colors.

In any sub-pixel P, an anode 221 of the light-emitting element 2a is electrically connected to a source T2 or a drain T3 of a transistor T of multiple transistors T included in the pixel circuit 10. FIG. 3 shows an example where the anode 221 is electrically connected to the source T2 of the transistor T. It will be noted that the source T2 and the drain T3 may be interchanged, that is, "T2" in FIG. 3 represents the drain, and "T3" in FIG. 3 represents the source.

In some examples, as shown in FIG. 3, the source T2 or the drain T3 of the thin film transistor is electrically connected to the anode 221 by a transfer electrode 222 located in the second source-drain conductive layer SD2.

In some embodiments, as shown in FIG. 1, the display area AA has a plurality of sub-pixel P (also called pixel), and each sub-pixel P includes a pixel circuit 10 and a light-emitting element 2a.

For example, as shown in FIG. 1, the display panel 100 includes sub-pixels P of at least three colors, and the sub-pixels P of the at least three colors include at least a sub-pixel of a first color, a sub-pixel of a second color and a sub-pixel of a third color. The first color, the second color and the third color are three primary colors (e.g., red, green and blue).

In some embodiments, as shown in FIGS. 3 and 4, the cathode layer 24 is configured to receive a first voltage signal vss, and the plurality of anodes 221 are configured to receive driving voltage signals. When the cathode layer 24 and the anode layer 22 respectively receive the first voltage signal vss and the driving voltage signal, the light-emitting functional layer 23 located between the cathode layer 24 and the anode layer 22 emits light.

Taking a light-emitting element 2a as an example, the pixel circuit 10 is connected to the anode 221 of the light-emitting element 2a, and the cathode layer 24 is connected to the first voltage signal line in the second source-drain conductive layer SD2. For example, a transfer electrode 222 is disposed in the anode layer 22, the cathode layer 24 is connected to the first voltage signal line in the second source-drain conductive layer SD2 by the transfer electrode 222, and the transfer electrode 222 is electrically insulated from the anode 221. The pixel circuit 10 provides a driving signal to the anode 221 of the light-emitting element 2a connected thereto, and the first voltage signal line provides a first voltage signal vss to the cathode layer 24. When the cathode layer 24 and the anode layer 22 respectively receive a first voltage Vss and a voltage of the driving signal, the light-emitting functional layer 23 located between the cathode layer 24 and the anode layer 22 emits light.

The driving signal generated by the pixel circuit 10 may be a driving voltage signal or a driving current signal. Here, only an exemplary description is made and is not used as a limitation in the present disclosure.

In some embodiments, as shown in FIG. 4, the encapsulation structure 21 has a stacked structure. The encapsulation structure 21 includes a first inorganic encapsulation layer 212, an organic encapsulation layer 211 and a second inorganic encapsulation layer 213. The first inorganic encapsulation layer 212 is closer to the back plate 1 than the organic encapsulation layer 211, the second inorganic encapsulation layer 213 is farther away from the back plate 1 than the organic encapsulation layer 211, and the second inorganic encapsulation layer 213 covers the first inorganic encapsulation layer 212 and the organic encapsulation layer 211.

The provision of the organic encapsulation layer 211 may not only play an encapsulation role for the light-emitting structure 2, but also serve as a stress release layer to release stress between inorganic layers (e.g., between the first inorganic encapsulation layer 212 and the second inorganic encapsulation layer 213), thereby preventing the encapsulation structure 21 from producing cracks and other defects due to action of stress. The provision of the first inorganic encapsulation layer 212 and the second inorganic encapsulation layer 213 may effectively isolate moisture and oxygen to prevent external moisture from entering, thereby improving an encapsulation effect of the encapsulation structure 21.

For example, the first inorganic encapsulation layer 212 may have a single-layer structure or a stacked structure.

For example, the first inorganic encapsulation layer 212 includes, but is not limited to, any of silicon nitride (SiNx), silicon oxide (SiOx), silicon oxynitride (SiON), aluminum oxide (Al₂O₃) and titanium oxide (TiO₂). Here, only an exemplary description is made and the present disclosure is not limited thereto.

It can be understood that in a case where the first inorganic encapsulation layer 212 has a stacked structure, the first inorganic encapsulation layer 212 may have a stacked film layer structure of aluminum oxide, silicon nitride and aluminum oxide; alternatively, the first inorganic encapsulation layer 212 may have a stacked film layer structure of titanium oxide, silicon oxynitride and titanium oxide.

For example, the first inorganic encapsulation layer 212 may be formed by PECVD, PEALD or sputtering.

For example, a thickness of the first inorganic encapsulation layer 212 is in a range of 50 nm to 2.5 μm, inclusive. For example, the thickness of the first inorganic encapsulation layer 212 is 50 nm, 1.2 μm or 2.5 μm.

Here, only an exemplary description is made and is not used as a limitation in the present disclosure.

For example, the second inorganic encapsulation layer 213 may adopt a single-layer structure or a stacked structure.

For example, a material of the second inorganic encapsulation layer 213 includes, but is not limited to, any of silicon nitride (SiNx), silicon oxide (SiOx), silicon oxynitride (SiON), aluminum oxide (Al₂O₃) and titanium oxide (TiO₂). Here, only an exemplary description is made and the present disclosure is not limited thereto.

It can be understood that in a case where the second inorganic encapsulation layer 213 adopts a stacked structure design, the second inorganic encapsulation layer 213 may have a stacked film layer structure of aluminum oxide, silicon nitride and aluminum oxide; alternatively, the second inorganic encapsulation layer 213 may have a stacked film layer structure of titanium oxide, silicon oxynitride and titanium oxide.

For example, the second inorganic encapsulation layer 213 may be formed by PECVD, PEALD or sputtering.

For example, a thickness of the second inorganic encapsulation layer 213 is in a range of 50 nm to 2.5 μm, inclusive.

For example, a material of the organic encapsulation layer 211 includes, but is not limited to, at least one of acrylate polymers, epoxy polymers or polyurethane polymers.

For example, the organic encapsulation layer 211 may be formed by inkjet printing, screen printing, flash evaporation, PECVD or PEALD.

Here, only an exemplary description is made and is not used as a limitation in the present disclosure.

In some examples, the encapsulation structure 21 further includes a first barrier layer, and the first barrier layer is located between the first inorganic encapsulation layer 212 and the organic encapsulation layer 211. The first barrier layer is made of an inorganic hydrophobic material, and the material of the first barrier layer includes, but is not limited to, aluminum oxide (Al₂O₃). A thickness of the first barrier layer is, for example, in a range of 30 nm to 1 μm, inclusive.

Here, only an exemplary description is made and is not used as a limitation in the present disclosure.

In some embodiments, as shown in FIGS. 3 and 4, the light-filter structure 3 includes a black matrix layer 31 and a plurality of filter portions 32. The black matrix layer 31 includes a first portion 311 located in the display area AA and a second portion 312 located in the peripheral area AN, the first portion 311 of the black matrix layer 31 is provided with a plurality of openings, and each filter portion 32 is located in an opening.

In the display panel 100, light emitted from the light-emitting element 2a passes through a filter portion 32 to exit. The light-filter structure 3 is provided to filter the light emitted by the light-emitting structure 2, so that the light within a target wavelength range can pass through the light-filter structure 3 to exit, and the light outside the target wavelength range is blocked by the light-filter structure 3. As a result, the color gamut of the light emitted by the light-emitting structure 2 may be enhanced, thereby enhancing the color gamut of the light emitted by the display panel 100 and further improving the display effect of the display panel 100. Moreover, the light-filter structure 3 may block the light reflected by the anode layer 22 in the light-emitting structure 2, so as to avoid light crosstalk of sub-pixels P of different colors.

For example, as shown in FIGS. 3 and 4, each filter portion 32 is disposed corresponding to at least one light-emitting element 2a. The plurality of filter portions 32 include, for example, a first color filter portion, a second color filter portion and a third color filter portion. The first color filter portion, the second color filter portion and the third color filter portion are each disposed opposite to at least one light-emitting element 2a.

For example, the light-emitting element 2a emits blue light; the blue light is converted into red light to exit after passing through the first color filter portion; the blue light is converted into green light to exit after passing through the second color filter portion; and the blue light remains as blue light to exit after passing through the third color filter portion.

In order to prevent the problem that other people besides the user may also clearly see a display image of the display apparatus, the display panel with an anti-peeping function has become one of research hotspots.

Some embodiments of the present disclosure provide a display panel 100 with an anti-peeping function. As shown in FIG. 4, the display panel further includes an anti-peeping organic layer 4 and anti-peeping structures 5. The anti-peeping organic layer 4 covers the display area AA and extends to the peripheral area AN. The anti-peeping structure 5 is at least located in the display area AA.

In some examples, the display panel 100 does not include the anti-peeping structure 5, when the light emitted by the light-emitting structure 2 passes through the light-filter structure 3 to exit, the light has a viewing angle of β, and β is, for example, less than or equal to 180°.

In some other examples, as shown in FIG. 4, the display panel 100 includes the anti-peeping structures 5, and the light emitted by the light-emitting structure 2 sequentially passes through the light-filter structure 3 and the anti-peeping structure 5 to exit. In this case, the light has a viewing angle of α, where α is less than β (α < β). For example, α is less than or equal to 50°. Here, only an exemplary description is made and is not used as a limitation in the present disclosure.

It can be seen that the provision of the anti-peeping structure 5 may converge and collimate the light exit from the display panel 100, and narrow an angle of the light exit from the display panel, thereby achieving an anti-peeping effect.

The provision of the anti-peeping organic layer 4 may increase a distance between the light-filter structure 3 and the anti-peeping structure 5, so as to improve a collimation effect of the anti-peeping structure 5 on light and well achieve an effect of narrowing the angle of the light exit from the display panel, thereby improving the anti-peeping effect of the display panel 100. The anti-peeping organic layer 4 may also play a planarization role, and provide a planarization surface for formation of the anti-peeping structure 5, thereby ensuring a good display quality.

For example, as shown in FIG. 4, the organic encapsulation layer 211 and the anti-peeping organic layer 4 have larger thicknesses than compared with other film layer structures (e.g., the light-filter structure 3 and the anti-peeping structures 5) in the display panel 100. A thickness of the organic encapsulation layer 211 is, for example, in a range of 12 μm to 17 μm, inclusive. For example, the thickness of the organic encapsulation layer 211 is 12 μm, 15 μm or 17 μm. A thickness of the anti-peeping organic layer 4 is, for example, in a range of 20 μm to 40 μm, inclusive. For example, the thickness of the anti-peeping organic layer 4 is 20 μm, 33 μm or 40 μm. Here, only an exemplary description is made and is not used as a limitation in the present disclosure.

Since the organic encapsulation layer 211 and the anti-peeping organic layer 4 have relatively large thicknesses, in a case where the organic encapsulation layer 211 and the anti-peeping organic layer 4 have the same edge positions, there will be a large step difference at the edge positions of the organic encapsulation layer 211 and the anti-peeping organic layer 4. Thus, in the subsequent manufacturing process, for example, during forming other film layer structures or during an integration process, the large step difference at the edge positions of the organic encapsulation layer 211 and the anti-peeping organic layer 4 may lead to process defects that may introduce a great risk.

In light of this, some embodiments of the present disclosure provide a display panel 100. As shown in FIG. 5, an edge of the anti-peeping organic layer 4 is located on a side of an edge of the organic encapsulation layer 211 away from the display area AA.

The edge of the anti-peeping organic layer 4 is disposed on a side of the edge of the organic encapsulation layer 211 away from the display area AA, so that the edges of the organic encapsulation layer 211 and the anti-peeping organic layer 4 have a certain interval, thereby avoiding overlapping of the edge positions of the organic encapsulation layer 211 and the anti-peeping organic layer 4. In this way, it is ensured that after the anti-peeping organic layer 4 is formed, there will be no large step difference at the edge positions of the organic encapsulation layer 211 and the anti-peeping organic layer 4, and a thickness of a portion of the film layer structure in the display panel 100 between the edge of the organic encapsulation layer 211 and the edge of the anti-peeping organic layer 4 gradually changes to form a gentle slope with a gradually changing height, thereby avoiding process defects caused by the step difference in the subsequent manufacturing process when the remaining film layer structures in the display panel 100 are formed. Therefore, the manufacturing yield of the display panel 100 may be improved, and the display effect of the display panel may be ensured.

For example, a material of the anti-peeping organic layer 4 includes, but is not limited to, at least one of acrylate polymers, epoxy polymers or polyurethane polymers.

For example, the anti-peeping organic layer 4 may be formed by inkjet printing, screen printing, flash evaporation, PECVD or PEALD.

Here, only an exemplary description is made and is not used as a limitation in the present disclosure.

In some embodiments, as shown in FIG. 5, the display panel 100 further includes at least one encapsulation dam 8 and an anti-crack structure 9 that are disposed in the peripheral area AN and surrounding the display area AA, and the anti-crack structure 9 is located on a side of the at least one encapsulation dam 8 away from the display area AA.

For example, as shown in FIG. 16, a single encapsulation dam 8 has an annular structure surrounding the display area AA, and the annular structure includes, but is not limited to, a rectangular ring. In a case where the display panel 100 includes a plurality of encapsulation dams 8, the plurality of annular encapsulation dams 8 are put on sequentially.

For example, a single encapsulation dam 8 includes a plurality of sub-portions arranged along a boundary line of the display area AA, and the plurality of sub-portions are disconnected.

In some examples, the plurality of sub-portions of the single encapsulation dam 8 are disposed around the display area AA and are arranged in a row along a boundary line of the display area AA.

In some other examples, the plurality of sub-portions of the single encapsulation dam 8 are disposed proximate to any side edge or a corner of the back plate 1.

For example, the back plate 1 is substantially in a rectangular shape, and a single encapsulation dam 8 includes at least four sub-portions. The four corners of the back plate 1 are each provided with a sub-portion thereat, and at least one sub-portion may be provided between any two of the sub-portions.

As another example, the back plate 1 is substantially in a rectangular shape, and a single encapsulation dam 8 includes a plurality of sub-portions, which are arranged linearly along at least one side edge of the back plate 1.

The specific design of the encapsulation dam 8 is adaptively designed depending on actual needs. Here, only an exemplary description is made and is not used as a limitation in the present disclosure.

For example, the anti-crack structure 9 has an annular structure surrounding the display area AA. The annular structure includes, but is not limited to, a rectangular ring. The specific design of the anti-crack structure 9 is adaptively designed depending on shapes of the display area AA and the peripheral area AN. Here, only an exemplary description is made and is not used as a limitation in the present disclosure.

For example, a shape of a longitudinal section of the encapsulation dam 8 includes, but is not limited to, a semicircle, a triangle, a rectangle or a trapezoid. The longitudinal section is a section taken along a plane perpendicular to an extending direction of the encapsulation dam 8.

The provision of the encapsulation dam 8 may, when the organic encapsulation layer 211 is formed, restrict the flow of the material of the organic encapsulation layer 211, so that a stop position of the edge of the organic encapsulation layer 211 may be maintained within a set range, and the material of the organic encapsulation layer 21 will not overflow outside the display panel 100, thereby ensuring the manufacturing yield and the display effect of the display panel 100. In addition, the encapsulation dam 8 may also protect a side surface of the film layer structure, such as the anode 221 and/or the light-emitting functional layer 23, located inside the encapsulation dam 8, so as to prevent the film layer structure located inside the encapsulation dam 8 from being bumped and damaged during manufacturing the display panel 100. When the anti-peeping organic layer 4 is formed, the encapsulation dam 8 may also restrict the flow of the material of the anti-peeping organic layer 4, so as to control a stop position of the edge of the anti-peeping organic layer 4 to be maintained within a set range and the material of the anti-peeping organic layer 4 not to overflow outside the display panel 100, thereby ensuring the manufacturing yield and the display effect of the display panel 100.

For example, as shown in FIG. 5, the display panel 100 includes m encapsulation dams 8, where m is a positive integer. For example, m is greater than or equal to 1 and less than or equal to 5 (1 ≤ m ≤ 5). In a case where m is greater than or equal to 2 (m ≥ 2), the m encapsulation dams 8 are arranged in sequence at intervals. An encapsulation dam 8 closest to the display area AA in the m encapsulation dams 8 is a first encapsulation dam 81. In a direction from the display area AA to the peripheral area AN, there are the first encapsulation dam 81, a second encapsulation dam 82, ..., an mth encapsulation dam 8m in sequence.

In some examples, m is greater than or equal to 2 and less than or equal to 3 (2 ≤ m ≤ 3).

It will be noted that the anti-crack structure 9 is located on a side of the at least one encapsulation dam 8 away from the display area AA, which means that the anti-crack structure 9 is located on a side of the outermost encapsulation dam 8 in the at least one encapsulation dam 8 away from the display area AA. For example, in a case where the display panel 100 includes one encapsulation dam 8, the encapsulation dam 8 is the first encapsulation dam 81, and the anti-crack structure 9 is located on an outer side of the first encapsulation dam 81; in a case where the display panel 100 includes two encapsulation dams 8, the two encapsulation dams 8 are the first encapsulation dam 81 and the second encapsulation dam 82, the second encapsulation dam 82 is located on an outer side of the first encapsulation dam 81, and the anti-crack structure 9 is located on an outer side of the second encapsulation dam 82; and the same applies to a case where the display panel 100 includes three or more encapsulation dams 8.

For example, as shown in FIGS. 5 to 12, an edge of the organic encapsulation layer 211 is located between the first encapsulation dam 81 and the display area AA.

It will be noted that the position of the edge of the organic encapsulation layer 211 is related to the manufacturing process and other factors. For example, the organic encapsulation layer 211 is formed by inkjet printing. Since the material of the organic encapsulation layer 211 has fluidity, during forming the organic encapsulation layer 211, the material of the organic encapsulation layer 211 may overflow outward to outside the set edge range. However, the edge position of the organic encapsulation layer 211 is at least located on an inner side of the outermost encapsulation dam 8 (the encapsulation dam 8 farthest away from the display area AA).

For example, an edge of the second inorganic encapsulation layer 213 is located on an outer side of the mth encapsulation dam 8. A distance between the edge of the second inorganic encapsulation layer 213 and the outermost encapsulation dam 8 in the at least one encapsulation dam 8 is in a range of 50 μm to 500 μm, inclusive.

In some examples, as shown in FIG. 5, the display panel 100 includes two encapsulation dams 8, an edge of the second inorganic encapsulation layer 213 is located on an inner side of the first encapsulation dam 81. A distance a between the edge of the second inorganic encapsulation layer 213 and an edge of the outermost encapsulation dam 8 in the at least one encapsulation dam 8 away from the display area AA is in a range of 50 μm to 500 μm, inclusive.

It can be understood that the number of the encapsulation dam(s) 8 included in the display panel 100 may be set as needed. Here, only an exemplary description is made and is not used as a limitation in the present disclosure.

For example, the display panel 100 includes only one encapsulation dam 8, and the encapsulation dam 8 is the first encapsulation dam 81. The edge of the anti-peeping organic layer 4 is located at any position between an edge of the first encapsulation dam 81 proximate to the display area AA and an edge of the anti-crack structure 9 away from the display area AA. The edge of the anti-peeping organic layer 4 may be located on a side surface of the first encapsulation dam 81 proximate to the display area AA, or located on an upper surface of the first encapsulation dam 81, or located on a side surface of the first encapsulation dam 81 away from the display area AA, or located between the first encapsulation dam 81 and the anti-crack structure 9, or located on the anti-crack structure 9.

Referring to the above description, it can be understood that the edge of the organic encapsulation layer 211 is located on an inner side of the first encapsulation dam 81, and the first encapsulation dam 81 has a certain width in a direction from the display area AA to the peripheral area AN. Therefore, the edge of the anti-peeping organic layer 4 is located on a side surface of the first encapsulation dam 81 proximate to the display area AA (in this case, a certain interval is maintained between the edge of the organic encapsulation layer 211 and the first encapsulation dam 81 as much as possible), or located at a position farther away from the display area AA. Thus, the positions of the edge of the organic encapsulation layer 211 and the edge of the anti-peeping organic layer 4 may be staggered, thereby avoiding the step difference caused by overlapping of the edge positions of the organic encapsulation layer 211 and the anti-peeping organic layer 4. The thickness of the portion of the film layer structure in the display panel 100 between the edge of the organic encapsulation layer 211 and the edge of the anti-peeping organic layer 4 gradually changes to form a gentle slope with a gradually changing height, thereby avoiding process defects caused by the step difference in the subsequent manufacturing process when the remaining film layer structures in the display panel 100 are formed. Therefore, the manufacturing yield of the display panel 100 may be improved, and the display effect of the display panel may be ensured.

It can be understood that the larger the interval between the edge of the anti-peeping organic layer 4 and the edge of the organic encapsulation layer 211, the smaller a slope of a gentle slope formed by a portion between the edge of the organic encapsulation layer 211 and the edge of the anti-peeping organic layer 4, the closer the gentle slope is to a plane, the smaller the step difference at the positions of the edge of the organic encapsulation layer 211 and the edge of the anti-peeping organic layer 4, and the higher the manufacturing yield of the display panel 100.

Moreover, as shown in FIG. 5, in a case where the edge of the anti-peeping organic layer 4 is farther away from the display area AA, for example, the edge of the anti-peeping organic layer 4 is located between the encapsulation dam 8 farthest away from the display area AA and the anti-crack structure 9, alternatively, the edge of the anti-peeping organic layer 4 is located on the anti-crack structure 9, the anti-peeping organic layer 4 covers the second inorganic encapsulation layer 213 and other inorganic film layers, and may also serve as a stress release layer to release stress in the inorganic layer(s) (e.g., the second inorganic encapsulation layer 213) covered thereby, thereby preventing the inorganic layer(s) from generating cracks and other defects due to action of stress and improving a bending ability of a portion of the film layer structure in the peripheral area AN of the display panel 100.

The following description will be made by considering an example where the display panel 100 includes two encapsulation dams 8, for example, the display panel 100 includes a first encapsulation dam 81 and a second encapsulation dam 82.

In some embodiments, as shown in FIG. 5, the edge of the anti-peeping organic layer 4 is located between an edge of the first encapsulation dam 81 proximate to the display area AA and an edge of the anti-crack structure 9 away from the display area AA.

In some embodiments, in a case where the display panel 100 includes a plurality of encapsulation dams 8, an edge of the anti-peeping organic layer 4 is located between two adjacent encapsulation dams 8.

For example, the display panel 100 includes a first encapsulation dam 81 and a second encapsulation dam 82, and an edge of the anti-peeping organic layer 4 is located between the first encapsulation dam 81 and the second encapsulation dam 82.

For example, the display panel 100 further includes a third encapsulation dam in addition to the first encapsulation dam 81 and the second encapsulation dam 82. An edge of the anti-peeping organic layer 4 is located between the first encapsulation dam 81 and the second encapsulation dam 82; alternatively, the edge of the anti-peeping organic layer 4 is located between the second encapsulation dam 82 and the third encapsulation dam.

The same applies to a case where the display panel 100 further includes a fourth encapsulation dam, a fifth encapsulation dam, and so on. Here, only an exemplary description is made and is not used as a limitation in the present disclosure.

In some embodiments, as shown in FIG. 6, in a case where the display panel 100 includes a plurality of encapsulation dams 8, an edge of the anti-peeping organic layer 4 is located above any encapsulation dam 8.

For example, an edge of the anti-peeping organic layer 4 is located above any encapsulation dam 8, which includes: the edge of the anti-peeping organic layer 4 is located on a side surface of any encapsulation dam 8 proximate to the display area AA, alternatively, the edge of the anti-peeping organic layer 4 is located on an upper surface of any encapsulation dam 8, alternatively, the edge of the anti-peeping organic layer 4 is located on a side surface of any encapsulation dam 8 away from the display area AA.

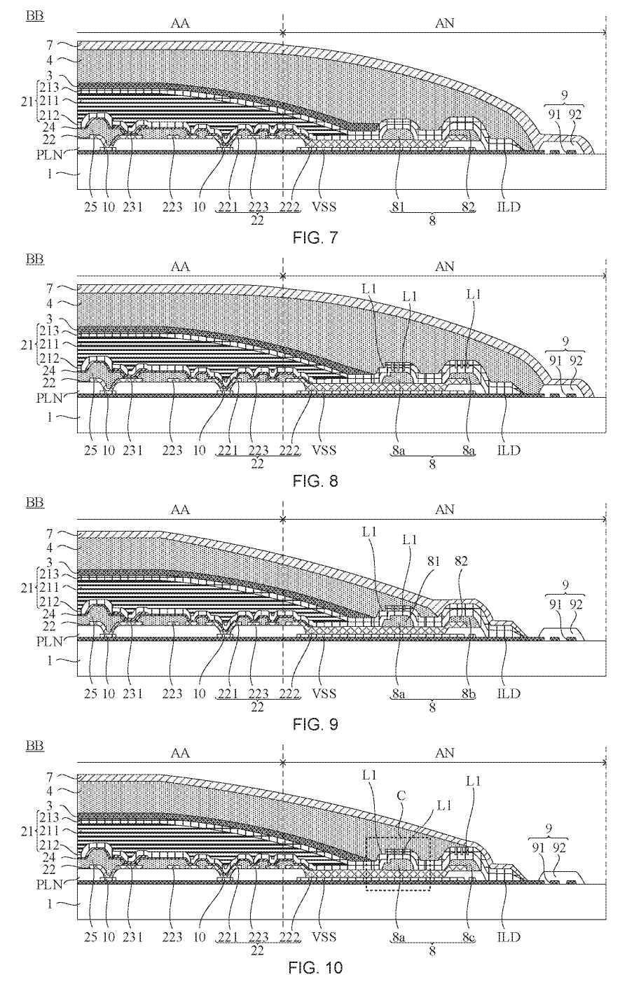

In some embodiments, as shown in FIG. 7, in a case where the display panel 100 includes a plurality of encapsulation dams 8, the edge of the anti-peeping organic layer 4 is located between an encapsulation dam 8 farthest away from the display area AA in the at least one encapsulation dam 8 and the anti-crack structure 9.

In some embodiments, as shown in FIG. 8, in a case where the display panel 100 includes a plurality of encapsulation dams 8, the edge of the anti-peeping organic layer 4 is located above the anti-crack structure 9.

For example, the edge of the anti-peeping organic layer 4 being located above the anti-crack structure 9 includes that the edge of the anti-peeping organic layer 4 is located on a side surface of the anti-crack structure 9 proximate to the display area AA, alternatively, the edge of the anti-peeping organic layer 4 is located on an upper surface of the anti-crack structure 9.

In some embodiments, as shown in FIGS. 8 and 9, at least one encapsulation dam 8 includes at least one first target encapsulation dam 8a, and the first target encapsulation dam 8a is located on a side of the edge of the anti-peeping organic layer 4 proximate to the display area AA.

The first target encapsulation dam 8a is located on a side of the edge of the anti-peeping organic layer 4 proximate to the display area AA. For example, the first target encapsulation dam 8a is the first encapsulation dam 81; alternatively, the first target encapsulation dams 8a are the first encapsulation dam 81 and the second encapsulation dam 82. The specific provision is made as needs and is not limited here.

For example, as shown in FIG. 8, in a case where the edge of the organic encapsulation layer 211 is located on a side of the first encapsulation dam 81 proximate to the display area AA, and the edge of the anti-peeping organic layer 4 is located between the second encapsulation dam 82 and the anti-crack structure 9, at least one of a side surface of the first target encapsulation dam 8a proximate to the display area AA, an upper surface of the first target encapsulation dam 8a, and a side surface of the first target encapsulation dam 8a away from the display area AA is provided with a first flow limiting structure L1 thereon, and at least one of a side surface of the second encapsulation dam 82 proximate to the display area AA, an upper surface of the second encapsulation dam 82, and a side surface of the second encapsulation dam 82 away from the display area AA is also provided with a first flow limiting structure L1 thereon.

For example, as shown in FIG. 9, in a case where the edge of the organic encapsulation layer 211 is located on a side of the first encapsulation dam 81 proximate to the display area AA, and the edge of the anti-peeping organic layer 4 is located between the first encapsulation dam 81 and the second encapsulation dam 82, at least one of a side surface of the first target encapsulation dam 8a proximate to the display area AA, an upper surface of the first target encapsulation dam 8a, and a side surface of the first target encapsulation dam 8a away from the display area AA is provided with a first flow limiting structure L1 thereon, and the second encapsulation dam 82 is not provided with a first flow limiting structure L1 thereon.

When the anti-peeping organic layer 4 is formed, the first target encapsulation dam 8a may block the flow of the material of the anti-peeping organic layer 4, and has a certain flow limiting effect. By providing the first flow limiting structure L1 on the first target encapsulation dam 8a, when the material of the anti-peeping organic layer 4 flows through the first flow limiting structure L1, the first flow limiting structure L1 blocks the flow of the material of the anti-peeping organic layer 4 and prevents the material of the anti-peeping organic layer 4 from flowing to the outside of the first flow limiting structure L1, thereby playing a role of controlling the position of the edge of the anti-peeping organic layer 4. As a result, the stop position of the edge of the anti-peeping organic layer 4 may be maintained within the set range, and the material of the anti-peeping organic layer 4 will not overflow outside the display panel 100, thereby ensuring the manufacturing yield and the display effect of the display panel 100.

In some embodiments, as shown in FIG. 9, in a case where the edge of the anti-peeping organic layer 4 is located between two adjacent encapsulation dams 8, at least one encapsulation dam 8 includes at least one second target encapsulation dam 8b, and the second target encapsulation dam 8b is located on a side of the edge of the anti-peeping organic layer 4 away from the display area AA and is adjacent to the edge of the anti-peeping organic layer 4. A first flow limiting structure L1 is disposed on a side of the second target encapsulation dam 8b proximate to the display area AA.

The second target encapsulation dam 8b is located on a side of the edge of the anti-peeping organic layer 4 away from the display area AA. For example, the second target encapsulation dam 8b is the second encapsulation dam 82. The specific provision is made as needs and is not limited here.

When the anti-peeping organic layer 4 is formed, the second target encapsulation dam 8b may block the flow of the material of the anti-peeping organic layer 4, and has a certain flow limiting effect. By providing the first flow limiting structure L1 on a side surface of the second target encapsulation dam 8b proximate to the display area AA, when the material of the anti-peeping organic layer 4 flows through the first flow limiting structure L1, the first flow limiting structure L1 blocks the flow of the material of the anti-peeping organic layer 4 and prevents the material of the anti-peeping organic layer 4 from flowing to the outside of the first flow limiting structure L1, thereby playing a role of controlling the position of the edge of the anti-peeping organic layer 4. As a result, the stop position of the edge of the anti-peeping organic layer 4 may be maintained within the set range, and the material of the anti-peeping organic layer 4 will not overflow outside the display panel 100, thereby ensuring the manufacturing yield and the display effect of the display panel 100.

In some embodiments, as shown in FIG. 10, in a case where the edge of the anti-peeping organic layer 4 is located on any encapsulation dam 8, at least one encapsulation dam 8 includes a third target encapsulation dam 8c, and the third target encapsulation dam 8c is located under the edge of the anti-peeping organic layer 4. A first flow limiting structure L1 is disposed on a side surface of the third target encapsulation dam 8c proximate to the display area AA and/or an upper surface of the third target encapsulation dam 8c.

The third target encapsulation dam 8c is located under the edge of the anti-peeping organic layer 4. For example, the third target encapsulation dam 8c is the first encapsulation dam 81 or the second encapsulation dam 82. The specific provision is made as needs and is not limited here.

When the anti-peeping organic layer 4 is formed, the third target encapsulation dam 8c may block the flow of the material of the anti-peeping organic layer 4, and has a certain flow limiting effect. By providing the first flow limiting structure L1 on a side surface of the third target encapsulation dam 8c proximate to the display area AA or an upper surface of the third target encapsulation dam 8c, when the material of the anti-peeping organic layer 4 flows through the first flow limiting structure L1, the first flow limiting structure L1 blocks the flow of the material of the anti-peeping organic layer 4 and prevents the material of the anti-peeping organic layer 4 from flowing to the outside of the first flow limiting structure L1, thereby playing a role of controlling the position of the edge of the anti-peeping organic layer 4. As a result, the stop position of the edge of the anti-peeping organic layer 4 may be maintained within the set range, and the material of the anti-peeping organic layer 4 will not overflow outside the display panel 100, thereby ensuring the manufacturing yield and the display effect of the display panel 100.

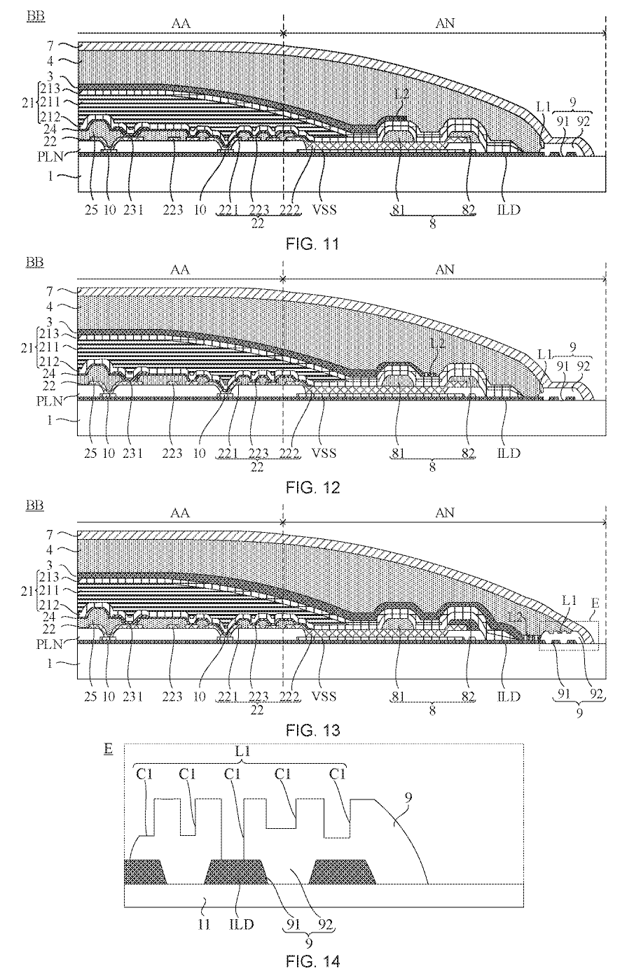

In some embodiments, as shown in FIG. 11, in a case where the edge of the anti-peeping organic layer 4 is located between an encapsulation dam 8 farthest from the display area AA in at least one encapsulation dam 8 and the anti-crack structure 9, a first flow limiting structure L1 is provided on a side surface of the anti-crack structure 9 proximate to the display area AA.

By providing a first flow limiting structure L1 on a side surface of the anti-crack structure 9 proximate to the display area AA, when the anti-peeping organic layer 4 is formed and when the material of the anti-peeping organic layer 4 flows through the first flow limiting structure L1, the first flow limiting structure L1 blocks the flow of the material of the anti-peeping organic layer 4 and prevents the material of the anti-peeping organic layer 4 from flowing to the outside of the first flow limiting structure L1, thereby playing a role of controlling the position of the edge of the anti-peeping organic layer 4. As a result, the stop position of the edge of the anti-peeping organic layer 4 may be maintained within the set range, and the material of the anti-peeping organic layer 4 will not overflow outside the display panel 100, thereby ensuring the manufacturing yield and the display effect of the display panel 100.

In some embodiments, as shown in FIGS. 13 and 14, in a case where the edge of the anti-peeping organic layer 4 is located on the anti-crack structure 9, a first flow limiting structure L1 is provided on a side surface of the anti-crack structure 9 proximate to the display area AA and/or an upper surface of the anti-crack structure 9.

By providing a first flow limiting structure L1 on a side surface of the anti-crack structure 9 proximate to the display area AA and/or an upper surface of the anti-crack structure 9, when the anti-peeping organic layer 4 is formed and when the material of the anti-peeping organic layer 4 flows through the first flow limiting structure L1, the first flow limiting structure L1 blocks the flow of the material of the anti-peeping organic layer 4 and prevents the material of the anti-peeping organic layer 4 from flowing to the outside of the first flow limiting structure L1, thereby playing a role of controlling the position of the edge of the anti-peeping organic layer 4. As a result, the stop position of the edge of the anti-peeping organic layer 4 may be maintained within the set range, and the material of the anti-peeping organic layer 4 will not overflow outside the display panel 100, thereby ensuring the manufacturing yield and the display effect of the display panel 100.

When the anti-peeping organic layer 4 is formed, the material of the anti-peeping organic layer 4 flows in a direction from the display area AA to the peripheral area AN. The shape of the edge of the anti-peeping organic layer 4 is related to the fluidity of the material of the anti-peeping organic layer 4 and the amount of the material flowing to the edge position. In a case where the material of the anti-peeping organic layer 4 has different flow distances in all directions, a boundary line of the anti-peeping organic layer 4 may present a patterned structure. For example, as shown in FIG. 15, the back plate 1 is substantially in a rectangular shape, the boundary line of the anti-peeping organic layer 4 is provided proximate to the back plate 1, and a certain side of the surface of the anti-peeping organic layer 4 presents a continuous pattern of alternating concave and convex shapes, or presents an irregular shape such as a wave shape.

As shown in FIG. 16, the provision of the first flow limiting structure L1 may control the position of the edge of the anti-peeping organic layer 4. Since the first flow limiting structure L1 is disposed on a side of the anti-crack structure 9 proximate to the display area AA and/or an upper surface of the anti-crack structure 9, the flow stop position of the material of the anti-peeping organic layer 4 (i.e., the edge of the anti-peeping organic layer 4 finally formed) matches the shape of the first flow limiting structure L1 provided on the anti-crack structure 9, thereby ensuring linearity of the edge of the anti-peeping organic layer 4 finally formed. The linearity mentioned here means that the boundary line of the anti-peeping organic layer 4 has a regular linear pattern, and the linear pattern matches a boundary line of the back plate 1 or a boundary line of the peripheral area AN.

Here, the description is made by taking an example where the first flow limiting structure L1 is provided on the anti-crack structure 9. In a case where the first flow limiting structure L1 is provided on encapsulation dam(s) 8 (e.g., the first encapsulation dam 81 and/or the second encapsulation dam 82), a similar effect is made on the shape of the edge of the anti-peeping organic layer 4 and the stop position of the anti-peeping organic layer 4, and details are not provided here.

It will be noted that whether the first flow limiting structure L1 is provided on the encapsulation dam 8 and the anti-crack structure 9 included in the display panel 100 may be provided as required.

For example, in a case where the edge of the anti-peeping organic layer 4 is located on the first encapsulation dam 81, or in a case where the edge of the anti-peeping organic layer 4 is located between the first encapsulation dam 81 and the second encapsulation dam 82, a portion of the first encapsulation dam 81 covered by the anti-peeping organic layer 4 may be provided with a first flow limiting structure L1 thereon, and a portion of the first encapsulation dam 81 not covered by the anti-peeping organic layer 4, the second encapsulation dam 82 and the anti-crack structure 9 are not provided with a first flow limiting structure L1 thereon.

As another example, in a case where the edge of the anti-peeping organic layer 4 is located on the second encapsulation dam 82, the first encapsulation dam 81 and a portion of the second encapsulation dam 82 covered by the anti-peeping organic layer 4 may be provided with a first flow limiting structure L1 thereon, and a portion of the second encapsulation dam 82 not covered by the anti-peeping organic layer 4 and the anti-crack structure 9 are not provided with a first flow limiting structure L1 thereon.

As another example, in a case where the edge of the anti-peeping organic layer 4 is located on the anti-crack structure 9, the first encapsulation dam 81, the second encapsulation dam 82 and a portion of the anti-crack structure 9 covered by the anti-peeping organic layer 4 may be provided with a first flow limiting structure L1 thereon, and a portion of the anti-crack structure 9 not covered by the anti-peeping organic layer 4 is not provided with a first flow limiting structure L1 thereon.

That is, in a case where the edge of the anti-peeping organic layer 4 is provided at any set position, the first flow limiting structure L1 may be selectively provided on the encapsulation dam 8 and/or the anti-crack structure 9 on an inner side of the edge of the anti-peeping organic layer 4, so as to prevent the material of the anti-peeping organic layer 4 from overflowing to the outside of the set position when the anti-peeping organic layer 4 is formed, so that the edge of the anti-peeping organic layer 4 finally formed will not be located outside the set position. The encapsulation dam 8 or the anti-crack structure 9 outside the set position are not provided with a first flow limiting L1 structure thereon.

Here, only an exemplary description is made and is not used as a limitation in the present disclosure.

In some embodiments, as shown in FIG. 17, the first flow limiting structure L1 includes at least one first groove C1. In a case where the first flow limiting structure L1 is disposed on the encapsulation dam 8 (e.g., the first encapsulation dam 81 or the second encapsulation dam 82), the first groove C1 extends through or partially extends through the encapsulation dam 8 from an upper surface of the encapsulation dam 8.

Considering an example where the first flow limiting structure L1 is provided on the first target encapsulation dam 8a, the first groove C1 may be provided on at least one of a side surface of the first target encapsulation dam 8a proximate to the display area AA, an upper surface of the first target encapsulation dam 8a or a side surface of the first target encapsulation dam 8a away from the display area AA.

For example, as shown in FIGS. 8, 9 and 10, the first groove C1 extends through or partially extends through the first target encapsulation dam 8a from an upper surface of the first target encapsulation dam 8a.

For example, a plurality of first grooves C1 are formed by photolithography.

In some examples, during forming the first target encapsulation dam 8a, the first groove(s) C1 are simultaneously formed.

In some other examples, after the first target encapsulation dam 8a is formed, the first groove(s) C1 are formed in the first target encapsulation dam 8a.

In some embodiments, as shown in FIGS. 17 to 20, a shape of the first groove C1 includes, but is not limited to, at least one of a circle, an ellipse or a polygon. In a case where the shape of the first groove C1 is a polygon, the shape of the first groove C1 may be a triangle, a rectangle, a rhombus, a trapezoid or a parallelogram.

For example, as shown in FIGS. 17, 18 and 20, a maximum value of a dimension of the first groove C1 is d1, and 5 μm ≤ d1 ≤ 20 μm. An interval d2 between any two adjacent first grooves C1 is d2, and 5 μm ≤ d2 ≤ 20 μm.

The maximum value of the dimension of the first groove C1 is d1, which means that in a case where the first grooves C1 are in a shape of a circle, in multiple circular first grooves C1, diameters of the multiple circles may be the same or not exactly the same, and the maximum value of the diameters of the circles is d1; in a case where the first groove C1 is in a shape of an ellipse, a dimension of a major axis of the ellipse is d1, and a dimension of a minor axis of the ellipse may be in a same range as the dimension of the major axis; in a case where the first groove C1 is in a shape of a triangle, a perpendicular line is drawn from any vertex of the triangle to an opposite side thereof, and a dimension from the vertex to the foot of the perpendicular is d1; in a case where the first groove C1 is in a shape of a rectangle, a length of a long side of the rectangle is d1, and a dimension of a short side of the rectangle may be in a same range as the dimension of the long side; and in a case where the first groove C1 is in a shape of a trapezoid or a parallelogram, a distance between two parallel sides of the trapezoid or the parallelogram is d1.

For example, in a case where the first groove C1 extends through or partially extends through the first target encapsulation dam 8a from the upper surface of the first target encapsulation dam 8a, a boundary line of the first groove C1 and a boundary line of the first target encapsulation dam 8a proximate to the display area AA may have an overlap or may have no overlap.

In some examples, as shown in FIG. 17, a side surface of the first target encapsulation dam 8a is provided with first grooves C1 thereon, and the first grooves C1 extend through the first target encapsulation dam 8a. In a case where orthogonal projections of the first grooves C1 on the back plate 1 and an orthographic projection of the first target encapsulation dam 8a on the back plate 1 have an overlap, a boundary line of the edge of the first target encapsulation dam 8a proximate to and/or away from the display area AA presents a continuous pattern of alternating concave and convex shapes.

In some other examples, a side surface of the first target encapsulation dam 8a is provided with first grooves C1 thereon, and the first grooves C1 do not extend through the first target encapsulation dam 8a. In a case where orthogonal projections of the first grooves C1 on the back plate 1 and an orthographic projection of the first target encapsulation dam 8a on the back plate 1 have an overlap, the side surface of the first target encapsulation dam 8a forms a stepped structure.

As shown in FIGS. 18, 19 and 20, in a case where the first grooves C1 provided on a side surface of the first target encapsulation dam 8a proximate to and/or away from the display area AA have no overlap with a boundary line of the side surface of the first target encapsulation dam 8a proximate to and/or away from the display area AA, the boundary line of the first target encapsulation dam 8a proximate to and/or away from the display area AA is in a shape of a straight line. Here, the boundary line of the first target encapsulation dam 8a proximate to and/or away from the display area AA is in a shape of a straight line, which means that the boundary line of the first target encapsulation dam 8a has a regular linear pattern, and the linear pattern matches the boundary line of the back plate 1 or the boundary line of the peripheral area AN.

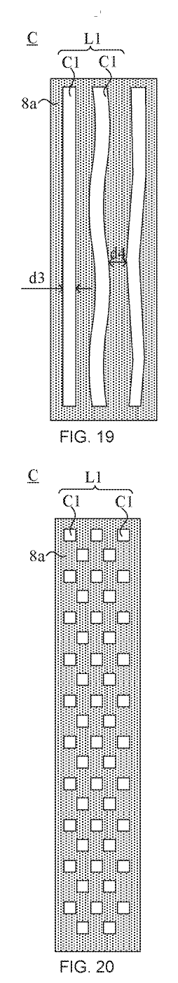

In some other embodiments, as shown in FIGS. 18 and 19, the first groove C1 is in a shape of a long strip, and the long strip-shaped first groove C1 extends in a straight line, a wavy line or a broken line.

For example, a width of the first groove C1 is d3, and 5 μm ≤ d3 ≤ 20 μm. An interval between any two adjacent first grooves C1 is d4, and 5 μm ≤ d4 ≤ 20 μm.

In some examples, as shown in FIG. 18, some of the plurality of first grooves C1 are each in a long strip shape (the first groove C1 extends in a straight line, a wavy line or a broken line), and the others of the plurality of first grooves C1 are each in a shape of a hole (the first groove C1 is in a circular, elliptical or polygonal shape).

For example, the plurality of first grooves C1 included in the first flow limiting structure L1 are arranged in two columns, multiple first grooves C1 in each column are arranged along the edge of the anti-peeping organic layer 4, and multiple first grooves C1 in each row are arranged in a direction perpendicular to the edge of the anti-peeping organic layer 4. The first grooves C1 in the first column are in a long strip shape, and the long strip shape extends in a row direction. The first grooves C1 in the second column are in a square shape, and any two adjacent first grooves C1 in two columns of first grooves C1 are aligned in the row direction.

In this case, a dimension of a long strip-shaped first groove C1 in the first column in a column direction is d3, and a dimension thereof in the row direction is not limited. An interval between any two adjacent first grooves C1 in the column direction is d4. A length of a square first groove C1 in the second column is d1, and an interval between any two adjacent first grooves C1 in the column direction is d2. There is no limitation on an interval between any two adjacent first grooves C1 in the row direction.

It can be understood that some of the plurality of first grooves C1 included in the first flow limiting structure L1 are each in a long strip shape, the plurality of long strip-shaped first grooves C1 are arranged in a column, and each long strip-shaped first groove C1 extends in the column direction. In this case, a dimension of any long strip-shaped first groove C1 in the row direction is d3, and a dimension thereof in the column direction is not limited.

It will be noted that in a case where the dimensions of the first grooves C1 are each maintained within a first set range (e.g., in a case where the first groove C1 is in a circular, elliptical or polygonal shape, the maximum value of the dimension of the first groove C1 is d1, and 5 μm ≤ d1 ≤ 20 μm; and in a case where the first groove C1 is in a long strip shape, the width of the first groove C1 is d3, and 5 μm ≤ d3 ≤20 μm), the plurality of first grooves C1 may form a hydrophobic structure, thereby achieving a function of limiting the flow of the material of the anti-peeping organic layer 4. Here, only an exemplary description is made and is not used as a limitation in the present disclosure. The shape and the dimension of the first groove C1 are not limited to the above examples, as long as the function of limiting the flow of the material of the anti-peeping organic layer 4 may be achieved. Accordingly, the first flow limiting structure L1 is not limited to the first groove C1, and any microstructure having the function of limiting the flow of the material of the anti-peeping organic layer 4 may be used as the first flow limiting structure L1.

In some other embodiments, the first groove C1 has a large dimension. During forming the anti-peeping organic layer 4, in a case where the material of the anti-peeping organic layer 4 flows through the first groove C1, part of the material will flow into the first groove C1, so that the material of the anti-peeping organic layer 4 that flows across the first groove C1 towards a direction away from the display area AA may be reduced, thereby playing a flow limiting role.

Here, only an exemplary description is made and is not used as a limitation in the present disclosure.

In some embodiments, as shown in FIG. 19, the first flow limiting structure L1 includes at least one first groove C1, and the first groove C1 is in a shape of a long ring surrounding the display area AA.

For example, in a case where the first groove C1 is in a ring shape surrounding the display area AA, the first flow limiting structure L1 may include a plurality of first grooves C1 which are put on sequentially.

In some other embodiments, as shown in FIGS. 17 to 20, in a case where the first flow limiting structure L1 includes a plurality of first grooves C1, the plurality of first grooves C1 are arranged into at least one column and a plurality of rows, multiple of first grooves C1 in each column are arranged along the edge of the anti-peeping organic layer 4, and first groove(s) C1 in each row are arranged in a direction perpendicular to the edge of the anti-peeping organic layer 4.

In a case where the first flow limiting structure L1 includes a plurality of first grooves C1, the plurality of first grooves C1 are evenly arranged. The direction along the edge of the anti-peeping organic layer 4 is referred to as a column direction, and the direction perpendicular to the edge of anti-peeping organic layer 4 is referred to as a row direction.

As shown in FIG. 17, the plurality of first grooves C1 are arranged in 4 columns (a column of first grooves C1 is shown in the dotted box shown in FIG. 17). As shown in FIG. 18, the plurality of first grooves are arranged in 2 columns. As shown in FIG. 19, the plurality of first grooves C1 are arranged in 3 columns. As shown in FIG. 20, the plurality of first grooves C1 are arranged in 5 columns.

For example, the first flow limiting structure L1 includes a column of first grooves C1, and the column of first grooves C1 may be any column of first grooves C1 in the first flow limiting structure L1 shown in FIGS. 17 to 20. The first grooves C1 in the same column may have the same or not exactly the same shapes.

In some examples, a column of first grooves C1 included in the first flow limiting structure L1 is a long strip-shaped first groove C1. As shown in FIG. 19, the shape of the first groove C1 may be a shape of any of multiple columns of first grooves C1 shown in FIG. 19.

The first groove C1 may also be in other shapes. Here, only an exemplary description is made and is not used as a limitation in the present disclosure.

For example, as shown in FIGS. 17 to 20, in a case where the first flow limiting structure L1 includes a plurality of columns of first grooves C1, the shapes of the first grooves C1 in different columns may be the same or not exactly the same.

In some embodiments, as shown in FIGS. 18 and 20, in a case where the plurality of first grooves C1 are arranged in a plurality of columns and a plurality of rows, first grooves C1 in any two adjacent rows are aligned or staggered in the column direction.

In a case where the first flow limiting structure L1 includes a plurality of first grooves C1, the plurality of first grooves C1 are evenly arranged, and any two adjacent first grooves C1 may be aligned (referring to FIG. 18) or staggered (referring to FIG. 20) in the row direction or the column direction.

In a case where the plurality of first grooves C1 are evenly arranged, when the material of the anti-peeping organic layer 4 flows onto the first grooves C1, the plurality of first grooves C1 arranged evenly have the same or approximately the same flow limiting effect on the material of the anti-peeping organic layer 4 in all directions, thereby ensuring the linearity of the edge of the anti-peeping organic layer 4 finally formed.

In a case where the first flow limiting structure L1 is disposed on a remaining encapsulation dam 8, the shape, the dimension and the location of the first groove C1 refer to that in the description of the first flow limiting structure L1 being disposed on the first target encapsulation dam 8a, and details are not repeated here.

In some embodiments, as shown in FIG. 13, the first encapsulation dam 81 adopts, for example, a single-layer structure, and the first encapsulation dam 81 is formed by using a portion of the pixel definition layer 25.

In some embodiments, as shown in FIG. 13, the second encapsulation dam 82 adopts, for example, a stacked structure, at least a portion of the second encapsulation dam 82 is located in the planarization layer PLN, and at least a portion of the second encapsulation dam 82 is located in the pixel defining layer 25. In this way, a height of the second encapsulation dam 82 is greater than a height of the first encapsulation dam 81, so that the flow of the organic encapsulation layer 211 may be effectively limited.

In some embodiments, as shown in FIG. 13, an upper surface of the insulating dielectric layer ILD is provided with at least one slit 91 thereon, and the slit 91 is disposed around the display area AA. The anti-crack structure 9 includes the at least one slit 91.

For example, referring to FIG. 14, the slit 91 extends through or partially extends through the insulating dielectric layer ILD from an upper surface of the insulating dielectric layer ILD.

During manufacturing the display panel, for example, a plurality of display panels 100 are formed on a whole motherboard, and then the motherboard is cut to obtain the plurality of display panels 100. In a process of cutting the motherboard, the substrate 11 in the display panel 100 and the film layer structure composed of the inorganic material on the substrate 11 are prone to cracking due to being subjected to stress during cutting. When the cracks extend to the display area AA, the display quality of the display panel 100 may be reduced.

By providing the at least one slit 91, when a crack is generated in a portion, located in the peripheral area AN, of the inorganic film layer (e.g., the insulating dielectric layer ILD) included in the display panel 100, in a process of the crack extending toward the display area AA and reaching the slit 91, the stress in the inorganic film layer is transferred to the slit 91 through the crack and is released, and an extension path of the crack is blocked and cut off by the slit 91, so that the crack cannot extend to the display area AA, thereby avoiding poor display caused by the crack generated in the inorganic film layer extending to the display area AA.

In some other embodiments, as shown in FIGS. 13 and 14, the planarization layer PLN includes an anti-crack pattern 92 located in the peripheral area AN. The anti-crack pattern 92 covers the at least one slit 91 and is disposed around the display area AA. The anti-crack structure 9 includes the at least one slit 91 and the anti-crack pattern 92.

The anti-crack pattern 92 is provided, and the anti-crack pattern 92 is made of an organic material. When the crack generated in the inorganic film layer extends to the anti-crack pattern 92, the anti-crack pattern 92 plays a role of a stress release structure, and the stress in the inorganic film layer is transferred to the slit 91 and the anti-crack pattern 92 through the crack and released. The extension path of the crack is blocked and cut off by the slit 91 and the anti-crack pattern 92, so that the crack cannot extend to the display area AA, thereby playing a role of crack prevention, and avoiding poor display caused by the crack generated in the inorganic film layer extending to the display area AA.

In some embodiments, as shown in FIG. 14, in a case where an upper surface of the anti-crack structure 9 is provided with at least one first groove C1 thereon, an orthogonal projection of the first groove C1 on the substrate 11 and an orthogonal projection of the slit 91 on the substrate 11 do not overlap, and the first groove C1 extends through or partially extends through the anti-crack pattern 92 from an upper surface of the anti-crack pattern 92.

For example, the anti-crack pattern 92 is provided to fill the slit 91, so that the slit 91 is filled with the organic material, and the anti-crack pattern 92 covers the slit 91, so that the slit 91 is covered by the organic film layer, thereby increasing the stress release effect of the anti-crack structure 9.

In some other embodiments, as shown in FIG. 14, in a case where a side surface of the anti-crack structure 9 proximate to the display area AA and/or an upper surface of the anti-crack structure 9 are provided with at least one first groove C1 thereon, an orthogonal projection of the first groove C1 on the substrate 11 and an orthogonal projection of the slit 91 on the substrate 11 overlap, and the first groove C1 partially extends through the anti-crack pattern 92 from an upper surface of the anti-crack pattern 92.

It can be understood that in a case where the first groove C1 extends through the anti-crack pattern 92 from an upper surface of the anti-crack pattern 92, if the first groove C1 and the slit 91 overlap in a direction perpendicular to the substrate 11, a portion of the slit 91 that should be filled with the organic material and/or a portion of a top of the slit 91 that should be covered by the anti-crack pattern 92 are exposed, and thus the stress release effect of the anti-crack structure 9 may be caused to be weakened.

Therefore, in a case where the anti-crack structure 9 is provided with the first groove C1 thereon, and the first groove C1 and the slit 91 overlap in the direction perpendicular to the substrate 11, the first groove C1 adopts a design of partially extending through the anti-crack pattern 92 from the upper surface of the anti-crack pattern 92. As a result, not only may a flow limiting effect be provided on the material of the anti-peeping organic layer 4, but also the stability of the anti-crack effect of the anti-crack structure 9 may not be affected. In a case where the first groove C1 and the slit 91 do not overlap in the direction perpendicular to the substrate 11, the first groove C1 may adopt a design of extending through or partially extending through the anti-crack pattern 92 from the upper surface of the anti-crack pattern 92. As a result, not only may a flow limiting effect be provided on the material of the anti-peeping organic layer 4, but also the stability of the anti-crack effect of the anti-crack structure 9 may not be affected.

In some embodiments, as shown in FIGS. 11, 12 and 13, an edge of a second portion 312 of the black matrix layer 31 of the light-filter structure 3 located in the peripheral area AN is provided with a second flow limiting structure L2 thereon, and the second flow limiting structure L2 is located between the edge of the organic encapsulation layer 211 and the edge of the anti-peeping organic layer 4.

As shown in FIG. 4, a side of the second portion 312 of the black matrix layer 31 is connected to the first portion 311 of the black matrix layer 31, and the other side thereof extends toward a direction away from the display area AA. The second portion 312 of the black matrix layer 31 is located on the outside of the first portion 311 thereof. It can be understood that the edge of the second portion 312 of the black matrix layer 31 is also the edge of the black matrix layer 31, and the edge of the black matrix layer 31 described below is also the edge of the second portion 312 of the black matrix layer 31.

By providing the second flow limiting structure L2 on the edge of the black matrix layer 31, when the material of the anti-peeping organic layer 4 flows through the second flow limiting structure L2, the second flow limiting structure L2 blocks the flow of the material of the anti-peeping organic layer 4 and prevents the material of the anti-peeping organic layer 4 from flowing to the outside of the second flow limiting structure L2, thereby playing a role of controlling the position of the edge of the anti-peeping organic layer 4. As a result, the stop position of the edge of the anti-peeping organic layer 4 may be maintained within the set range, and the material of the anti-peeping organic layer 4 will not overflow outside the display panel 100, thereby ensuring the manufacturing yield and the display effect of the display panel 100.

For example, as shown in FIGS. 11, 12 and 13, the edge of the black matrix layer 31 is located between the edge of the organic encapsulation layer 211 and the edge of the anti-peeping organic layer 4, and the second flow limiting structure L2 is disposed on the edge of the black matrix layer 31. Therefore, the position of the second flow limiting structure L2 is related to the position of the edge of the anti-peeping organic layer 4. The second flow limiting structure L2 is located inside the edge of the anti-peeping organic layer 4 to achieve a flow limiting effect on the material of the anti-peeping organic layer 4.

In some embodiments, the second flow limiting structure L2 includes at least one second groove C2 extending through or partially extending through the black matrix layer 31 from an upper surface of the black matrix layer 31.

Referring to FIGS. 17 to 20, a shape, a dimension, an arrangement and an achieved effect of the second groove C2 may be the same as those of the first groove C1. Reference may be made to the description corresponding to the first groove C1 above, and details are not repeated here.

In some embodiments, as shown in FIGS. 11 and 12, the black matrix layer 31 covers at least one encapsulation dam 8, at least one encapsulation dam 8 in the plurality of encapsulation dams 8 included in the display panel 100 is not covered by the black matrix layer 31, and the edge of the anti-peeping organic layer 4 is located outside the encapsulation dam 8 not covered by the black matrix layer 31. In this case, the edge of the black matrix layer 31, the encapsulation dam 8 covered by the edge of the black matrix layer 31, and the encapsulation dam 8 not covered by the black matrix layer 31 may all be provided with a flow limiting structure (a first flow limiting structure L1 and/or a second flow limiting structure L2) thereon.

For example, as shown in FIG. 11, the edge of the black matrix layer 31 is located on the first encapsulation dam 81. In this case, the edge of the black matrix layer 31 may be provided with the second flow limiting structure L2 thereon.

In some other embodiments, the edge of the black matrix layer 31 covers all the encapsulation dams 8 included in the display panel 100, the edge of the black matrix layer 31 is located on an encapsulation dam 8 farthest away from the display area AA, and the edge of the anti-peeping organic layer 4 is located outside all the encapsulation dams 8. In this case, the edge of the black matrix layer 31 and the encapsulation dam 8 covered by the edge of the black matrix layer 31 may both be provided with a flow limiting structure (a first flow limiting structure L1 and/or a second flow limiting structure L2) thereon.

In some other embodiments, referring to FIG. 13, in a case where the edge of the black matrix layer 31 covers all the encapsulation dams 8 included in the display panel 100 and the edge of the anti-peeping organic layer 4 is located on the anti-crack structure 9, the edge of the black matrix layer 31 is located between the outermost encapsulation dam 8 and the anti-crack structure 9, or located on a side surface of the anti-crack structure 9, or located on the anti-crack structure 9. The edge of the black matrix layer 31 may be provided with a second flow limiting structure L2, and a portion of the anti-crack structure 9 (the side surface thereof proximate to the display area AA and the upper surface thereof) not covered by the black matrix layer 31 may also be provided with a first flow limiting structure L1 thereon.

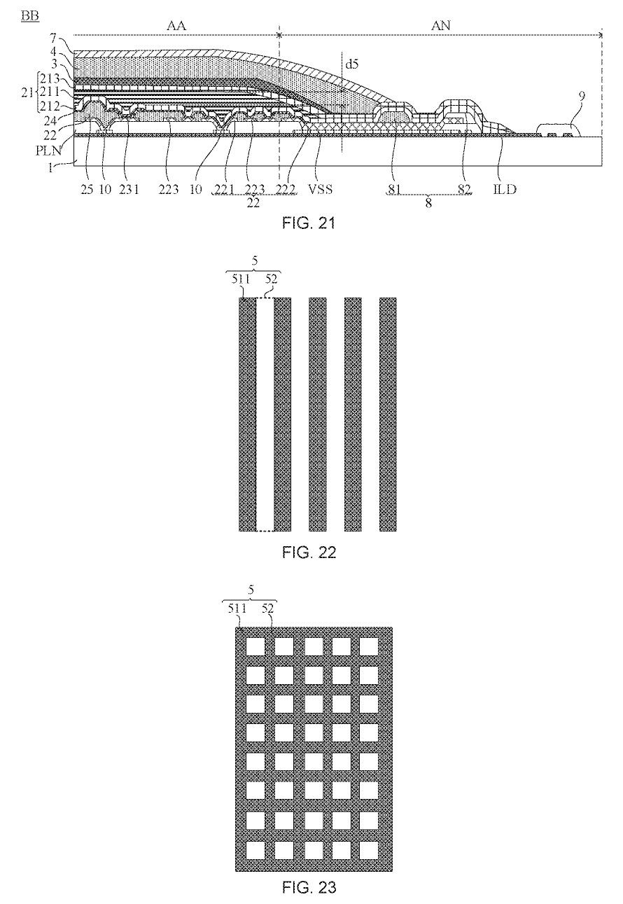

In some embodiments, as shown in FIG. 21, the material of the organic encapsulation layer 211 includes, but is not limited to, at least one of acrylic resin, epoxy resin, phenolic resin, polyamide resin and polyimide resin; a thickness of the organic encapsulation layer 211 is d5, and 1 μm ≤ d5 ≤ 4 μm.

For example, the organic encapsulation layer 211 is formed by exposure and development.

Compared with a case of forming the organic encapsulation layer 211 by inkjet printing, forming the organic encapsulation layer 211 by exposure and development may accurately control the position of the edge of the organic encapsulation layer 211, so that the position of the edge of the organic encapsulation layer 211 formed is accurate, and the edge of the organic encapsulation layer 211 may be formed on an inner side of the first encapsulation dam 81. As a result, the edge of the organic encapsulation layer 211 formed and the edge of the anti-peeping organic layer 4 may be spaced apart by a set distance, and a step difference generated at the edge of the anti-peeping organic layer 4 is small, so as to avoid process defects caused by the step difference when forming the remaining film layer structures in the display panel 100 in the subsequent manufacturing process, thereby improving the manufacturing yield of the display panel 100 and ensuring the display effect of the display panel.

It will be noted that in a case where the organic encapsulation layer 211 is formed by exposure and development, the position of the edge of the anti-peeping organic layer 4 and the arrangement of the first flow limiting structure L1 and the second flow limiting structure L2 may refer to the previous description, so as to further avoid an influence of the step difference generated at the edge of the organic encapsulation layer 211 and the edge of the anti-peeping organic layer 4 on the remaining film layer structures in the display panel 100. Details are not repeated here.

In some embodiments, as shown in FIG. 4, the display panel 100 further includes a spacer layer 6. The spacer layer 6 adopts an inorganic material. For example, the material of the spacer layer 6 includes, but is not limited to, any of silicon nitride (SiNx), silicon oxide (SiOx) or silicon oxynitride (SiON). Here, only an exemplary description is made and the present disclosure is not limited thereto.

For example, a thickness of the spacer layer 6 is in a range of 0.3 μm to 1 μm, inclusive.

The provision of the spacer layer 6 may isolate moisture and oxygen to effectively prevent the external moisture from entering the anti-peeping organic layer 4, so as to avoid affecting a light-transmitting effect of the anti-peeping organic layer 4 by the moisture entering the anti-peeping organic layer 4, and ensure a good light-transmitting effect of the anti-peeping organic layer 4, thereby ensuring the display quality of the display panel 100. Moreover, the material of the spacer layer 6 has a high light refractive index, and the light emitted by the light-emitting structure 2 may be sufficiently reflected when passing through the spacer layer 6, thereby improving the light extraction rate of the display panel 100 and further improving the visual effect of the display panel 100.

In a case where the edge of the organic encapsulation layer 211 and the edge of the anti-peeping organic layer 4 are at the same positions, there is a large step difference at the position of the edge of the anti-peeping organic layer 4.

Referring to the previous description, by separating the edge of the organic encapsulation layer 211 from the edge of the anti-peeping organic layer 4, the step difference at the position of the edge of the anti-peeping organic layer 4 may be reduced. In this way, during forming the spacer layer 6, the integrity of the spacer layer 6 may be well guaranteed, thereby ensuring an effect that the spacer layer 6 may prevent the external moisture from entering the anti-peeping organic layer 4.

In some embodiments, as shown in FIG. 4, the display panel 100 further includes, for example, a protective layer 7, and the protective layer 7 covers the light-emitting structure 2, the light-filter structure 3, the anti-peeping organic layer 4 and the anti-peeping structure 5. The protective layer 7 at least covers the anti-peeping structure 5.

For example, the protective layer 7 also covers the spacer layer 6.

The provision of the protective layer 7 may effectively isolate moisture and oxygen to effectively prevent external moisture from entering the anti-peeping structure 5, so as to avoid affecting a light-transmitting effect of the anti-peeping structure 5 by the moisture entering the anti-peeping structure 5, thereby ensuring the display quality of the display panel 100.

Referring to the previous description, by separating the edge of the organic encapsulation layer 211 from the edge of the anti-peeping organic layer 4, the step difference at the position of the edge of the anti-peeping organic layer 4 may be reduced. In this way, during forming the protective layer 7, the integrity of the protective layer 7 may be well guaranteed to avoid breakage of the protective layer 7.

The material of the protective layer 7 includes, but is not limited to, any of silicon nitride (SiNx), silicon oxide (SiOx), silicon oxynitride (SiON), aluminum oxide (Al₂O₃) and titanium oxide (TiO₂). Here, only an exemplary description is made and the present disclosure is not limited thereto.

For example, the protective layer 7 is formed by CVD or ALD.

In some embodiments, as shown in FIG. 22, the anti-peeping structure 5 includes a light-shielding portion 51 and light-transmitting areas 52 defined by the light-shielding portion 51.

In some embodiments, as shown in FIG. 22, the anti-peeping structure 5 includes a plurality of light-shielding strips 511 disposed at intervals. Any two adjacent light-shielding strips 511 have a light-transmitting area 52 therebetween, and the light-shielding strips 511 and light-transmitting areas 52 are alternately disposed in a set direction.

The alternate provision of the light-shielding strips 511 and the light-transmitting areas 52 may converge and collimate the light emitted by the light-emitting structure 2 in two directions (up-down directions or left-right directions), thereby realizing the peek-proofing of the display panel 100 in two directions.

In some embodiments, as shown in FIG. 23, the anti-peeping structure 5 is in a grid shape.

For example, as shown in FIG. 23, the light-shielding portion 51 is provided therein with a plurality of light-transmitting areas 52 arranged in an array.

For example, as shown in FIG. 4, the light-transmitting areas 52 may be filled with the protective layer 7, or may be filled with transparent materials separately.

The provision of the grid-shaped light-shielding portion 51 may converge and collimate the light emitted by the light-emitting structure 2 in four directions (up-down directions and left-right directions), thereby realizing the peek-proofing of the display panel 100 in four directions.

In some embodiments, the plurality of sub-pixels P (referring to FIG. 1) included in the display panel 100 are arranged in X rows and Y columns, where X and Y are positive integers.

For example, in a case where the anti-peeping structure 5 includes a plurality of light-shielding strips 511 arranged at intervals, any light-transmitting area 52 is disposed corresponding to sub-pixels P in the A row or in the B column, where A and B are positive integers, 1 ≤ A ≤ X, and 1 ≤ B ≤ Y.

For example, in a case where the anti-peeping structure 5 is in a grid shape, any light-transmitting area 52 is disposed corresponding to at least one sub-pixel P.

The foregoing descriptions are merely specific implementations of the present disclosure, but the protection scope of the present disclosure is not limited thereto. Any person skilled in the art could conceive of changes or replacements within the technical scope of the present disclosure, which shall all be included in the protection scope of the present disclosure. Therefore, the protection scope of the present disclosure shall be subject to the protection scope of the claims.

What is claimed is:

1. A display panel having a display area and a peripheral area surrounding the display area; the display panel comprising:
a back plate;
an encapsulation structure disposed on the back plate, wherein the encapsulation structure comprises an organic encapsulation layer, and the organic encapsulation layer covers the display area;
an anti-peeping organic layer disposed on a side of the encapsulation structure away from the back plate and covering the display area, wherein an orthographic projection of an edge of the anti-peeping organic layer on the back plate is spaced apart from an orthographic projection of an edge of the organic encapsulation layer on the back plate; and
an anti-peeping structure disposed on a side of the anti-peeping organic layer away from the encapsulation structure and at least located in the display area.

2. The display panel according to claim 1, wherein the edge of the anti-peeping organic layer is located on a side of the edge of the organic encapsulation layer away from the display area.

3. The display panel according to claim 1, wherein the organic encapsulation layer extends from the display area to the peripheral area.

4. The display panel according to claim 2, further comprising:
at least one encapsulation dam and an anti-crack structure that are disposed in the peripheral area and surrounding the display area, wherein the anti-crack structure is located on a side of the at least one encapsulation dam away from the display area; and an encapsulation dam, closest to the display area, in the at least one encapsulation dam is a first encapsulation dam, wherein
the edge of the organic encapsulation layer is located between the first encapsulation dam and the display area; and
the edge of the anti-peeping organic layer is located on a side of the first encapsulation dam away from the display area.

5. The display panel according to claim 2, further comprising a plurality of encapsulation dams, wherein the edge of the anti-peeping organic layer is located on a side of the plurality of encapsulation dams away from the display area.

6. The display panel according to claim 5, wherein the display panel comprises two encapsulation dams, and an encapsulation dam, further away from the display area, in the two encapsulation dams is a second encapsulation dam; and the edge of the anti-peeping organic layer is located on a side of the second encapsulation dam away from the display area.

7. The display panel according to claim 1, further comprising:
a light-filter structure disposed between the encapsulation structure and the anti-peeping organic layer, wherein the light-filter structure comprises a plurality of filter portions arranged at intervals.

8. The display panel according to claim 7, wherein the edge of the anti-peeping organic layer is located on a side of the filter portions away from the display area.

9. The display panel according to claim 7, wherein the light-filter structure further comprises a black matrix layer, the black matrix layer is provided with a plurality of openings therein, and each filter portion is located in an opening.

10. The display panel according to claim 9, wherein an edge of the black matrix layer is located between the edge of the organic encapsulation layer and the edge of the anti-peeping organic layer.

11. The display panel according to claim 9, wherein the edge of the anti-peeping organic layer is located on a side of an edge of the black matrix layer away from the display area.

12. The display panel according to claim 9, wherein an edge of the black matrix layer is located on a side of the edge of the organic encapsulation layer away from the display area.

13. The display panel according to claim 9, further comprising one or more encapsulation dams disposed in the peripheral area and surrounding the display area, wherein the black matrix layer covers at least one of the one or more encapsulation dams.

14. The display panel according to claim 13, wherein an encapsulation dam, closest to the display area, in the one or more encapsulation dams is a first encapsulation dam; and
an edge of the black matrix layer is located on a side of the first encapsulation dam away from the display area.

15. The display panel according to claim 13, wherein the display panel comprises a plurality of encapsulation dams, wherein
the black matrix layer cover all the encapsulation dams; or
an edge of the black matrix layer is located above an encapsulation dam furthest away from the display area in the plurality of encapsulation dams.

16. The display panel according to claim 13, wherein the display panel comprises a plurality of encapsulation dams; and
the display panel further comprises an anti-crack structure located on a side of the plurality of encapsulation dams away from the display area, wherein
an edge of the black matrix layer is located between an edge, proximate to the display area, of an encapsulation dam furthest away from the display area in the plurality of encapsulation dams and the anti-crack structure.

17. The display panel according to claim 1, wherein the anti-peeping structure comprises a light-shielding portion, and the light-shielding portion is provided therein with a plurality of light-transmitting areas arranged in an array.

18. The display panel according to claim 17, wherein the anti-peeping structure is in a grid shape.

19. The display panel according to claim 1, further comprising:
a protective layer covering the anti-peeping organic layer and the anti-peeping structure.

20. A display apparatus, comprising:
the display panel according to claim 1; and
a driving circuit board electrically connected to the display panel.
